(19) United States
(12) Patent Application Publication
(10) Pub. No.: US 2019/0305519 A1
(43) Pub. Date: Oct. 3, 2019

(54) QUANTUM CASCADE LASER

(71) Applicant: SUMITOMO ELECTRIC INDUSTRIES, LTD., Osaka (JP)

(72) Inventor: Jun-ichi HASHIMOTO, Osaka (JP)

(73) Assignee: SUMITOMO ELECTRIC INDUSTRIES, LTD., Osaka (JP)

(21) Appl. No.: 16/365,338

(22) Filed: Mar. 26, 2019

(30) Foreign Application Priority Data
Apr. 3, 2018 (JP) 2018-071695

(51) Int. Cl. H01S 5/34; H01S 5/227; H01S 5/042

(52) U.S. Cl. CPC H01S 5/3402; H01S 5/0425; H01S 5/2275; H01S 5/2272

(57) ABSTRACT

A quantum cascade laser includes: a laser structure including first and second end faces, a semiconductor mesa, and a supporting base; and a first electrode on the semiconductor mesa. The first and second end faces are arranged in a direction of a first axis. The semiconductor mesa has first and second mesa portions which are disposed between the first and second end faces. The semiconductor mesa has a first mesa width at a boundary between the first and second mesa portions, and a second mesa width smaller than the first mesa width at an end of the second mesa portion, and has a width varying from the first mesa width in a direction from the boundary to the second end face. The second mesa portion includes a high specific-resistance region having a specific-resistance higher than that of a conductive semiconductor region included in the first and second mesa portions.

### BACKGROUND OF THE INVENTION

### Field of the Invention

The present invention relates to a quantum cascade laser. This application claims the benefit of priority from Japanese Patent application No. 2018-071695 filed on Apr. 3, 2018, which is herein incorporated by reference in its entirety.

### Related Background Art

Thierry Aellen, Stephane Blaser, Mattias Beck, Daniel Hofstetter, and Jerome Faist, “Continuous-wave distributed-feedback quantum-cascade lasers on a Peltier cooler,” Applied Physics Letters 83(10), pp 1929-1931 October 2003, referred to as Non-Patent Document 1, discloses a quantum cascade laser.

### SUMMARY OF THE INVENTION

A quantum cascade laser according to one aspect of the present embodiment includes: a laser structure including a first end face, a second end face, a semiconductor mesa, and a supporting base, the first end face and the second end face being arranged in a direction of a first axis, the semiconductor mesa having a first mesa portion and a second mesa portion, the supporting base mounting the semiconductor mesa; and a first electrode disposed on the semiconductor mesa. The first mesa portion extends from the first end face. The first mesa portion and the second mesa portion are disposed between the first end face and the second end face. The second mesa portion has an end. The semiconductor mesa has a first mesa width at a boundary between the first mesa portion and the second mesa portion. The second mesa portion has a second mesa width at the end of the second mesa portion. The second mesa width is smaller than the first mesa width. The second mesa portion has a width varying from the first mesa width in a direction from the boundary to the second end face. The semiconductor mesa includes a conductive semiconductor region and a core layer. The conductive semiconductor region and the core layer extending from the first end face beyond the boundary. The second mesa portion includes a high specific-resistance region, and the high specific-resistance region having a specific resistance higher than that of the conductive semiconductor region.

### BRIEF DESCRIPTION OF THE DRAWINGS

The above-described objects and the other objects, features, and advantages of the present invention become more apparent from the following detailed description of the preferred embodiments of the present invention proceeding with reference to the attached drawings.

FIG. 1 is a schematic view showing a quantum cascade laser according to an example of the embodiment.

FIG. 2A is a schematic cross sectional view taken along line IIa-IIa shown in FIG. 1.

FIG. 2B is a schematic cross sectional view taken along line IIb-IIb shown in FIG. 1.

FIG. 2C is a schematic cross sectional view taken along line IIc-IIc shown in FIG. 1.

FIG. 2D is a schematic cross sectional view taken along the line IId-IId shown in FIG. 1.

FIG. 3A is a graph showing the lateral near-field patterns of the quantum cascade lasers DV and CV.

FIG. 3B is a graph showing the vertical near-field patterns of the quantum cascade lasers DV and CV.

FIG. 3C is a graph showing the lateral far-field patterns of the quantum cascade lasers DV and CV.

FIG. 3D is a graph showing the vertical far-field patterns of the quantum cascade lasers DV and CV.

FIG. 4A is a schematic view showing an optical apparatus including the quantum cascade laser and the optical waveguide structure that are optically coupled with each other through lenses.

FIG. 4B is a schematic view showing an optical apparatus including the quantum cascade laser and the optical waveguide structure that are optically coupled with each other.

FIG. 5A is a schematic cross sectional view showing a major step in a method for fabricating a quantum cascade laser according to an example of the embodiment.

FIG. 5B is a schematic cross sectional view showing a major step in the method according to the example of the embodiment.

FIG. 5C is a schematic cross sectional view showing a major step in the method according to the example of the embodiment.

FIG. 6A is a schematic cross sectional view showing a major step in the method according to the example of the embodiment.

FIG. 6B is a schematic plan view showing a major step in the method according to the example of the embodiment.

FIG. 6C is a schematic plan view showing a major step in the method according to the example of the embodiment.

FIG. 7A is a schematic plan view showing a major step in the method according to the example of the embodiment.

FIG. 7B is a schematic cross sectional view showing a major step in the method according to the example of the embodiment.

FIG. 7C is a schematic cross sectional view showing a major step in the method according to the example of the embodiment.

FIG. 7D is a schematic cross sectional view showing a major step in the method according to the example of the embodiment.

FIG. 7E is a schematic cross sectional view showing a major step in the method according to the example of the embodiment.

FIG. 8A is a schematic cross sectional view showing a quantum cascade laser in the example according to the embodiment.

FIG. 8B is a cross sectional view taken along line VIIb-VIIb shown in FIG. 8A.

FIG. 8C is a cross sectional view taken along line VIIb-VIIb shown in FIG. 8A.

FIG. 9A is a schematic cross sectional view showing a quantum cascade laser in another example according to the embodiment.

FIG. 9B is a cross sectional view taken along line IXb-IXb shown in FIG. 9A.

FIG. 9C is a cross sectional view taken along line IXb-IXb shown in FIG. 9A.

FIG. 10A is a schematic cross sectional view showing an exemplary quantum cascade laser according to still another example of the embodiment.

FIG. 10B is a cross sectional view taken along line Xb-Xb shown in FIG. 10A.

FIG. 10C is a cross sectional view taken along line Xb-Xb shown in FIG. 10A.

FIG. 11A is a schematic cross sectional view showing a quantum cascade laser according to yet another example of the embodiment.

FIG. 11B is a cross sectional view taken along line XIb-XIb shown in FIG. 11A.

FIG. 11C is a cross sectional view taken along line XIb-XIb shown in FIG. 11A.

FIG. 12A is a schematic cross sectional view showing a quantum cascade laser according to further example of the embodiment.

FIG. 12B is a cross sectional view taken along line XIIb-XIIb shown in FIG. 12A.

FIG. 12C is a cross sectional view taken along line XIIb-XIIb shown in FIG. 12A.

FIG. 13A is a schematic cross sectional view showing a quantum cascade laser according to still further example of the embodiment.

FIG. 13B is a schematic cross sectional view showing a quantum cascade laser according to yet further example of the embodiment.

FIG. 14A is a schematic cross sectional view showing a quantum cascade laser according to further another example of the embodiment.

FIG. 14B is a schematic cross sectional view showing a quantum cascade laser according to still further another example of the embodiment.

FIG. 15 is a schematic cross sectional view showing a quantum cascade laser according to yet further another example of the embodiment.

### DESCRIPTION OF THE EMBODIMENTS

The inventor's findings reveal that a quantum cascade laser lasing in mid-infrared wavelengths (3 to 20 micrometers) has a large angular divergence in emission levels. What is sought is to provide a mid-infrared quantum cascade laser allowing the radiation angle to fall within a desired angular range.

Further, quantum cascade lasers require a large amount of electrical power input in lasing. In particular, such an electrical power is injected into the waveguide of a quantum cascade laser, resulting in that the large power dissipation raises the operating temperature of the quantum cascade laser. Making the waveguide of the quantum cascade laser become varied along the waveguide in width may allow the control of the radiation angle thereof, thereby making the angular divergence reduced into a desired angular range. Such a variation in shape of the waveguide may also alter the temperature distribution in the quantum cascade laser, which may enlarge the difference between the two extreme values in the temperature distribution.

What is needed is to provide a quantum cascade laser with a structure making the angular divergence in intensity of emitted light adjustable and making the thermal tolerance thereof high.

A description will be give of examples according to the embodiment.

A quantum cascade laser according to an example of the embodiment includes: (a) a laser structure including a first end face, a second end face, a semiconductor mesa, and a supporting base, the first end face and the second end face being arranged in a direction of a first axis, the semiconductor mesa having a first mesa portion and a second mesa portion, the supporting base mounting the semiconductor mesa; and (b) a first electrode disposed on the semiconductor mesa. The first mesa portion extends from the first end face. The first mesa portion and the second mesa portion are disposed between the first end face and the second end face. The second mesa portion has an end. The semiconductor mesa has a first mesa width at a boundary between the first mesa portion and the second mesa portion. The second mesa portion has a second mesa width at the end of the second mesa portion. The second mesa width is smaller than the first mesa width. The second mesa portion has a width varying from the first mesa width in a direction from the boundary to the second end face. The semiconductor mesa includes a conductive semiconductor region and a core layer. The conductive semiconductor region and the core layer extend from the first end face beyond the boundary. The second mesa portion includes a high specific-resistance region, and the high specific-resistance region has a specific resistance higher than that of the conductive semiconductor region.

The quantum cascade laser provides the semiconductor mesa with not only the first mesa portion but also the second mesa portion that has a mesa width varying from the first mesa width in the direction from the boundary between the first mesa portion and the second mesa portion to the second end face. The second mesa portion provides, with a small radiation angle, the light that is emitted from the second end face. The second mesa portion is provided with the high specific-resistance semiconductor region, which can restrict the amount of electric power supplied from the first electrode to the second mesa portion, thereby preventing the concentration of current from occurring in the narrowed end portion of the second mesa portion.

In the quantum cascade laser according to an example of the embodiment, the high specific-resistance region reaches the second end face.

The quantum cascade laser is provided with the high specific-resistance semiconductor region at and around the second end face, thereby preventing the concentration of current from occurring in the narrow end of the second mesa portion.

In the quantum cascade laser according to an example of the embodiment, the high specific-resistance region reaches a top face of the second mesa portion,

The quantum cascade laser allows the high specific-resistance semiconductor region to be disposed along the top face of the second mesa portion, thereby providing the uppermost portion of the second mesa portion with the high specific-resistance semiconductor region, which can prevent the first electrode from making contact with the conductive semiconductor of the narrowed second mesa portion.

In the quantum cascade laser according to an example of the embodiment, the high specific-resistance region separates the core layer in the second mesa portion away from the second end face.

The quantum cascade laser is provided with the high specific-resistance semiconductor region which separates the core region in the narrowed second mesa portion away from the second end face, thereby preventing the concentration of current from occurring in the core region in the narrowed second mesa portion.

In the quantum cascade laser according to an example of the embodiment, the high specific-resistance region separates the conductive semiconductor region in the second mesa portion away from the second end face.

The quantum cascade laser is provided with the high specific-resistance semiconductor region, which separates the conductive semiconductor region in the narrowed second mesa portion away from the second end face, thereby preventing the concentration of current from occurring in the conductive semiconductor region in the narrowed second mesa portion.

In the quantum cascade laser according to an example, the high specific-resistance region extends from a top of the second mesa portion to the supporting base.

The quantum cascade laser is provided with the high specific-resistance semiconductor region, which extends in the direction from the top of the second mesa portion to the supporting base, thereby preventing the concentration of current from occurring in the vicinity of the second end face.

In the quantum cascade laser according to an example of the embodiment, the first electrode has an end away from the end of the second mesa portion, and the high specific-resistance region is away from the second end face.

The quantum cascade laser separates the high specific-resistance semiconductor region away from the second end face to prevent current from flowing into the narrow mesa portion in the vicinity of the second end face.

The quantum cascade laser according to an example of the embodiment further includes an insulating film. The second mesa portion includes a top face, and the top face has a first area and a second area. The first area and the second area are arranged in the direction of the first axis. The first area extends from the second area to the second end face. The high specific-resistance semiconductor region extends from the second area in a direction of a second axis intersecting the first axis, and the insulating film is disposed on the first area.

The quantum cascade laser is provided with the insulating film on the first area of the second mesa portion, thereby preventing the concentration of current from occurring near the second end face.

In the quantum cascade laser according to an example of the embodiment, the first electrode is away from the second end face. The quantum cascade laser according to an example of the embodiment further includes a second electrode that is disposed on the supporting base, and the second electrode has an end away from the second end face.

The quantum cascade laser separates either or both of the first electrode or the second electrode away from the second end face to prevent the concentration of current from occurring in the vicinity of the second end face.

Teachings of the present invention can be readily understood by considering the following detailed description with reference to the accompanying drawings shown as examples. Referring to the accompanying drawings, a description will be given of a quantum cascade laser, an optical apparatus, and a method for fabricating a quantum cascade laser according to examples of the present embodiment below. To facilitate understanding, identical reference numerals are used, where possible, to designate identical elements that are common to the figures.

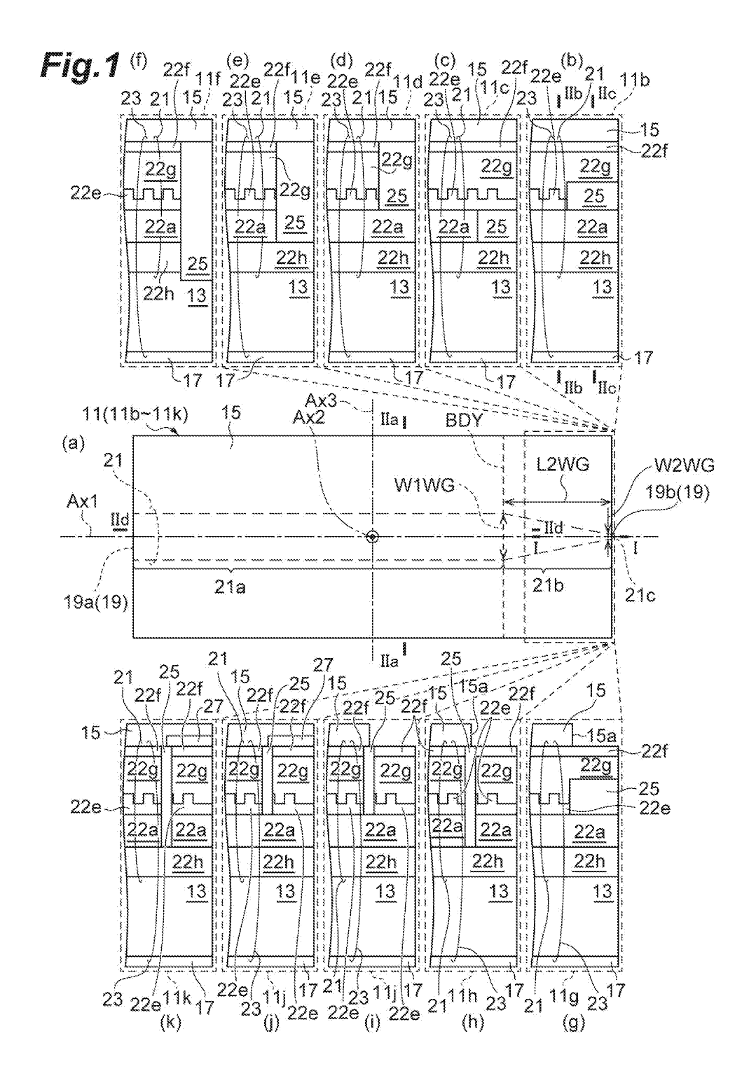

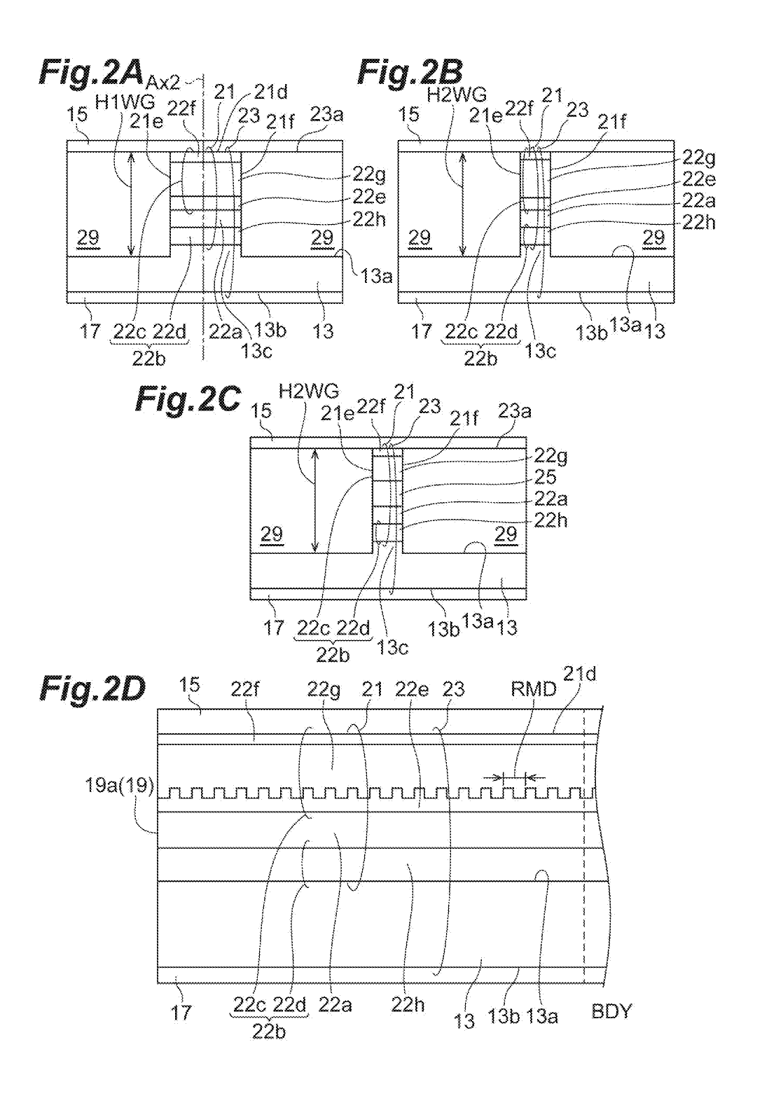

FIG. 1 schematically shows an exemplary quantum cascade laser according to an embodiment. Specifically, part (a) of FIG. 1 is a schematic plan view showing the quantum cascade laser according to the embodiment, and parts (b) to (k) of FIG. 1 are schematic cross sectional views, taken along line I-I shown in part (a) of FIG. 1, showing various emitting end structures, referred to as respective reference symbols 11b, 11c, 11d, 11e, 11f, 11g, 11h, 11i, 11j, and 11k, each of which the quantum cascade laser according to the embodiment may have. These reference symbols are used in the following description with reference to parts (b) to (k) of FIG. 1. FIG. 2A is a schematic cross sectional view, taken along line IIa-IIa shown in part (a) of FIG. 1. FIGS. 2B and 2C are schematic cross sectional views, taken along lines IIb-IIb and IIc-IIc shown in part (b) of FIG. 1. FIG. 2D is a schematic cross sectional view, taken along line IId-IId shown in part (a) of FIG. 1.

The quantum cascade laser 11 (11b to 11k) includes a laser structure 23. The laser structure 23 includes a supporting base 13, an end face 19 and a semiconductor mesa 21. The end face 19 includes a first end face 19a and a second end face 19b. The first and second end faces 19a and 19b are arranged in a direction of a first axis Ax1. The supporting base 13 has a principal face 13a and a back face 13b, and the principal face 13a is opposite to the back face 13b. The supporting base 13 mounts the semiconductor mesa 21 thereon. The semiconductor mesa 21 extends on the principal face 13a.

The quantum cascade laser 11 (1 lb to 11k) further includes a first electrode 15. The first electrode 15 is disposed on the laser structure 23, and specifically, is located on the semiconductor mesa 21. The first electrode 15 extends along the semiconductor mesa 21.

The quantum cascade laser 11 (11b to 11k) further includes a second electrode 17. The second electrode 17 is disposed on the laser structure 23, and specifically, is located on the supporting base 13 of the laser structure 23. The second electrode 17 extends on the back face 13b of the supporting base 13.

The first and second electrodes 15 and 17 are separated away from each other on the laser structure 23.

The semiconductor mesa 21 includes a first mesa portion 21a and a second mesa portion 21b, and the second mesa portion 21b has an end 21c. The first and second mesa portions 21a and 21b are disposed between the first and second end faces 19a and 19b. The first and second mesa portions 21a and 21b are arranged in the direction from one of the first and second end faces 19a and 19b to the other, for example, in the direction of the first axis Ax1 in the present example.

The semiconductor mesa 21 has a first mesa width W1WG at the boundary BDY between the first and second mesa portions 21a and 21b, and the second mesa portion 21b has a second mesa width W2WG at the end 21c. The second mesa width W2WG is smaller than the first mesa width W1WG. The second mesa portion 21b has a mesa width ranging from the first mesa width W1WG to the second mesa width W2WG, and the mesa width at one position between the end 21c and the boundary BDY is equal to or larger than that at another position closer to the end 21c than the one position. In particular, the second mesa portion 21b has a mesa width that gradually varies from the first mesa width W1WG in the direction from the boundary BDY to the second end face 19b. The first mesa portion 21a has a strip shape extending in the direction from the boundary BDY to the first end face 19a, and may be provided with a mesa width substantially equal to the first mesa width W1WG. The first mesa width W1WG is in the range of, for example, 3 to 20 micrometers, and the second mesa width W2WG is in the range of, for example, 1 to 5 micrometers. The second mesa portion 21b has a length L2WG (defined as the distance between the second end face 19b and the boundary BDY), which is in the range of, for example, 100 to 1000 micrometers. The semiconductor mesa 21 is mounted on the supporting base 13, which may have a ridge 13c extending along the semiconductor mesa 21 in the direction of the first axis Ax1. The ridge 13c serves as a pedestal for the semiconductor mesa 21 and provides the semiconductor waveguide with a height higher than that of the semiconductor mesa 21. The sum of the pedestal 13c and the first mesa portion 21a in height is referred to as the height H1WG, and the sum of the pedestal 13c and the second mesa portion 21b in height is referred to as the height H2WG. The heights H1WG and H2WG, each of which is referred to as a waveguide height, are in the range of, for example, 5 to 15 micrometers. The semiconductor mesa 21 is provided with one side face 21e and the other side face 21f, which are used to define the mesa width of the semiconductor mesa 21 as the interval between the side faces 21e and 21f.

The semiconductor mesa 21 includes a core layer 22a and a conductive semiconductor region 22b, and the core layer 22a extends from the first end face 19a beyond the boundary BDY to the second mesa portion 21a. Specifically, the conductive semiconductor region 22b includes an upper conductive semiconductor layer 22c and a lower conductive semiconductor layer 22d. The core layer 22a is disposed between the upper and lower conductive semiconductor layers 22c and 22d. In the first and second mesa portions 21a and 21b, the core layer 22a and the upper and lower conductive semiconductor layers 22c and 22d extend in the direction of the first axis Ax1 and the lower conductive semiconductor layer 22d, the core layer 22a, and the upper conductive semiconductor layer 22c are arranged in the direction of the second axis Ax2 intersecting the first axis Ax1. The core layer 22a receives carriers from the electrode to lase in the mid-infrared wavelength range of about 3 to 20 micrometers.

The second mesa portion 21b includes a high specific-resistance semiconductor region 25 which has a specific resistance higher than that of the conductive semiconductor region 22b, specifically the upper and lower conductive semiconductor layers 22c and 22d. The high specific-resistance semiconductor region 25 can extend from the side face 21e of the semiconductor mesa 21 to the other side face 21f across the semiconductor mesa 21.

The first electrode 15 is disposed on the semiconductor mesa 21, and may extend along the first and second mesa portions 21a and 21b. Specifically, the first electrode 15 makes contact with the top face 21d of the semiconductor mesa 21. The second electrode 17 is disposed on the supporting base 13 of the laser structure 23, and specifically, makes contact with the back face 13b. The first mesa portion 21a extends from the first end face 19a to the second mesa portion 21b.

The semiconductor mesa 21 may provide the second mesa portion 21b with one or more mesa parts each having a mesa width monotonically-varying in the direction from the boundary BDY to the second end face 19b, and specifically, the second mesa portion 21b has a mesa width monotonically-decreasing toward the second end face 19b from the first mesa width W1WG to the second mesa width W2WG. The second mesa portion 21b is provided with one mesa width at a far position, which is positioned away from the second end face 19b by a first distance, and another mesa width at a near position, which is positioned away from the second end face 19b by a second distance. The near position is closer to the second end face 19b than the far position (the first distance is greater than the second distance), and the one mesa width is not smaller than the other mesa width. In the semiconductor mesa 21 having a monotonously decreasing mesa width, the mesa width at the far position of the first distance may be larger than that at the near position of the second distance (the first distance is larger than the second distance).

In the present example according to the embodiment, the second mesa portion 21b has a width gradually decreasing in the direction from the boundary BDY to the end 21c to form a tapered shape as shown in a portion (a) of FIG. 1, and the first mesa portion 21a has a strip shape with a uniform mesa width.

The quantum cascade laser 11 provides the semiconductor mesa 21 with the second mesa portion 21b having a mesa width monotonically changing from the first mesa width W1WG in the direction from the boundary BDY to the second end face 19b. The second mesa portion 21b makes it possible to narrow the radiation angle of light emitted from the second end face 19b of the quantum cascade laser 11. The second mesa portion 21b is provided with the high specific-resistance semiconductor region 25, which can reduce the amount of electric power that the first electrode 15 supplies to the second mesa portion 21b, thereby preventing the concentration of current from occurring in the narrowed mesa, i.e., the second mesa portion 21b.

The laser structure 23 may be provided with a semiconductor embedding region 29 which embeds the semiconductor mesa 21. Specifically, the semiconductor embedding region 29 embeds both the first and second mesa portions 21a and 21b. The semiconductor embedding region 29 may include at least one of, for example, undoped semiconductor and semi-insulating semiconductor, each of which has a high specific resistance.

The quantum cascade laser 11 (11b and 11g) is provided with the high specific-resistance semiconductor region 25, which separates the diffraction grating layer 22e and a part of the upper cladding layer 22g of the upper conductive semiconductor layer 22c away from the second end face 19b, thereby preventing the concentration of current from occurring at or around the second end face 19b.

The quantum cascade laser 11c is provided with the high specific-resistance semiconductor region 25, which separates the core layer 22a away from the second end face 19b, thereby preventing the concentration of current from occurring at or around the second end face 19b.

The quantum cascade laser 11d is provided with the high specific-resistance semiconductor region 25, which separates the upper conductive semiconductor layer 22c away from the second end face 19b, thereby preventing the concentration of current from occurring at or around the second end face 19b.

The quantum cascade laser 11 (11e) is provided with the high specific-resistance semiconductor region 25, which separates the core layer 22a and the upper conductive semiconductor layer 22c away from the second end face 19b, thereby preventing the concentration of current from occurring at or around the second end face 19b.

The quantum cascade laser 11 (11f) is provided with the high specific-resistance semiconductor region 25, which separates the core layer 22a and the conductive semiconductor region 22b away from the second end face 19b, thereby preventing the concentration of current from occurring at or around the second end face 19b.

Referring to parts (b) to (g) of FIG. 1, the quantum cascade laser 11 (11b to 11g) is provided with the high specific-resistance semiconductor region 25 that reaches the second end face 19b. The quantum cascade laser 11 (11b to 11g) is provided with the high specific-resistance semiconductor region, thereby preventing the concentration of current from occurring at or around the end 21c of the narrowed second mesa portion 21b. If needed, the high specific-resistance semiconductor region 25 may extend along the second end face 19b in the direction of the third axis Ax3 intersecting the first and second axes Ax1 and Ax2.

Referring to parts (d) to (f) and (h) to (k) of FIG. 1, the quantum cascade laser 11 (11d to 11f and 11h to 11k) is provided with the high specific-resistance semiconductor region 25, which reaches the top face of semiconductor mesa 21 to form the top face of the second mesa portion 21b. The quantum cascade laser 11 (11d to 11f and 11h to 11k) allows the first electrode 15 to make contact with not the conductive semiconductor in the narrowed second mesa portion 21b but the top face of the high specific-resistance semiconductor region 25 in the second mesa portion 21b.

Referring to parts (b), (c) and (g) of FIG. 1, the quantum cascade laser 11 (11b, 11c, and 11g) is provided with the high specific-resistance semiconductor region 25, which is disposed away from the top of the second mesa portion 21b. The quantum cascade laser 11 (11b, 11c, and 11g) makes the high specific-resistance semiconductor region 25 distant from the top face of the second mesa portion 21b, allowing the carriers to circumvent the high specific-resistance semiconductor region 25 and thereby to flow in the second mesa portion 21b away from the second end face 19b.

Referring to parts (c), (e), (f), (h) and (k) of FIG. 1, the quantum cascade laser 11 (11c, 11e, 11f, 11h, and 11k) is provided with the high specific-resistance semiconductor region 25, which separates, from the second end face 19b, the core layer 22a emitting light in the second mesa portion 21b in response to the injection of current. The quantum cascade laser 11 (11c, 11e, 11f, 11h, and 11k) is provided with the high specific-resistance semiconductor region 25, which separates the core layer 22a from the second end face 19b, thereby preventing the concentration of current from occurring in the second mesa portion 21b narrowed in the vicinity of the second end face 19b.

Referring to part (f) of FIG. 1, the quantum cascade laser 11 (11f) is provided with the high specific-resistance semiconductor region 25, which extends from the top of the narrowed second mesa portion 21b to the supporting base 13 to separate both the conductive semiconductor region 22b and the core layer 22a from the second end face 19b. The quantum cascade laser 11 (11f) provides the narrowed second mesa portion 21b with the high specific-resistance semiconductor region 25, which makes the flow of current away from the second end face 19b, thereby preventing the concentration of current from occurring in the conductive semiconductor region 22b of the second mesa portion 21b narrowed in the vicinity of the second end face 19b.

Referring to part (f) of FIG. 1, the quantum cascade laser 11 (11f) allows the high specific-resistance semiconductor region 25 to extend from the top face of the second mesa portion 21b to the supporting base 13, so that the high specific-resistance semiconductor region 25 prevents the concentration of current from occurring in the vicinity of the second end face 19b.

Further, referring to part (f) of FIG. 1, the quantum cascade laser 11 (11f) makes the conductive semiconductor (for example, the core layer 22a, the upper conductive semiconductor layer 22c and the lower conductive semiconductor layer 22d) terminate away from the second end face 19b. Specifically, the high specific-resistance semiconductor region 25 is disposed so as to separate the core layer 22a and the conductive semiconductor region 22b in the second mesa portion 21b from the second end face 19b, so that the quantum cascade laser 11 (11f) allows the high specific-resistance semiconductor region 25 to prevent the concentration of current from occurring in the narrowed second mesa portion 21b.

Referring to parts (g), (h) and (i) of FIG. 1, the quantum cascade laser 11 (11g, 11h, and 11i) provides the first electrode 15 with the end 15a remote from the second end face 19b. The high specific-resistance semiconductor region 25 and the first electrode 15 are disposed to be distant from the second end face 19b, thereby preventing the concentration of current from occurring at or around the end 21c of the narrowed second mesa portion 21b.

Referring to parts (b) to (f), (j) and (k) of FIG. 1, the quantum cascade laser 11 (11b to 11f, 11j and 11k) provides the first electrode 15 with the end 15a remote from the second end face 19b. The high specific-resistance semiconductor region 25 and the first electrode 15 are disposed distant from the second end face 19b, thereby preventing the concentration of current from occurring around the end 21c of the narrowed second mesa portion 21b.

Referring to parts (h) and (i) of FIG. 1, the quantum cascade laser 11 (11h and 11i) is provided with the high specific-resistance semiconductor region 25, which is disposed remote from the second end face 19b and extends downward from the top face of the second mesa portion 21b in the direction of the axis intersecting the principal face 13a (e.g., the second axis Ax2), so that the high specific-resistance semiconductor region 25 makes a part or all of the conductive semiconductor (for example, the core layer 22a, the upper conductive semiconductor layer 22c, and the lower conductive semiconductor layer 22d), which lies in the first and second mesa portions 21a and 21b, terminate in the second mesa portion 21b. In addition, the high specific-resistance semiconductor region 25 also makes a part or all of the conductive semiconductor (for example, the core layer 22a, the upper conductive semiconductor layer 22c, and the lower conductive semiconductor layer 22d), which extends in the direction from the second end face 19b to the first end face 19a, terminate in the second mesa portion 21b.

The quantum cascade laser 11 (11h and 11i) is provided with the high specific-resistance semiconductor region 25, which prevents the concentration of current from occurring in the vicinity of the end 21c in the narrowed second mesa portion 21b.

The first electrode 15 may be provided with the end 15a which is separated away from the second end face 19b. The separation of the high specific-resistance semiconductor region 25 and the end 15a from the second end face 19b prevents current from flowing into the narrowed mesa portion in the vicinity of the second end face 19b. In the present example according to the embodiment, the end 15a of the first electrode 15 is disposed on the high specific-resistance semiconductor region 25.

As shown in parts (j) and (k) of FIG. 1, the quantum cascade laser 11 (11j and 11k) further includes an insulating film 27, such as a silicon-based inorganic insulator. The insulating film 27 extends from the second end face 19b and is disposed on the second mesa portion 21b. The insulating film 27 is disposed on the second mesa portion 21b in the quantum cascade laser 11 (11j and 11k) to prevent the concentration of current from occurring in the vicinity of the second end face 19b.

If necessary, as shown in parts (b) to (f) of FIG. 1, the quantum cascade laser 11 (11b to 11f) may be provided with the insulating film 27. The insulating film 27 is disposed on the second mesa portion 21b. The insulating film 27 extends from the second end face 19b to terminate away from the boundary BDY, and cover the top face of the second mesa portion 21b. In particular, the insulating film 27 is interposed between the first electrode 15 and the laser structure 23, so that the insulating film 27 can prevent the first electrode 15 from making contact with the laser structure 23, thereby avoiding the occurrence of the concentration of current in the end portion of the narrowed second mesa portion 21b.

As shown in part (g) of FIG. 1, the quantum cascade laser 11 (11g) is provided with the first and second electrodes 15 and 17, either or both of which may be disposed away from the second end face 19b. The separation of the first electrode 15 and/or the second electrode 17 away from the second end face 19b makes it possible to reduce the current density in the vicinity of the second end face 19b. In particular, the following arrangements are applicable to the quantum cascade laser 11 (11b to 11k): both the first and second electrodes 15 and 17 are away from the second end face 19b; the first electrode 15 is away from the second end face 19b and the second electrode 17 reaches the second end face 19b; and the first electrode 15 reaches the second end face 19b and the second electrode 17 is away from the second end face 19b.

An exemplary quantum cascade laser 11 (11b to 11g)

High specific-resistance semiconductor region 25: semi-insulating or undoped III-V compound semiconductor, such as InP, GaInAs, AlInAs, GaInAsP, and AlGaInAs

Upper conductive semiconductor layer 22c: n-type InP upper cladding layer 22g, if necessary, which may include a diffraction grating layer 22e (for example, n-type GaInAs) and a contact layer 22f (for example, n-type GaInAs)

Core layer 22a: GaInAs/AlInAs or GaInAsP/AlInAs

Lower conductive semiconductor layer 22d: n-type InP lower cladding layer 22h

Supporting base 13: n-type InP

Semiconductor embedding region 29: III-V compound semiconductor, such as semi-insulating or undoped InP, GaInAs,

AlInAs, GaInAsP, and AlGaInAs

First and second electrodes 15 and 17: Ti/Au, Ti/Pt/Au, or Ge/Au

N-type dopant: silicon (Si), sulfur (S), tin (Sn), selenium (Se).

### EXAMPLE

One quantum cascade laser (referred to as “DV”) includes a semiconductor mesa having a first mesa width W1WG of 5 micrometers and a second mesa width W2WG of 1 micrometer. The quantum cascade laser DV has a mesa height of 6.8 micrometers. Another quantum cascade laser (referred to as “CV”) includes a semiconductor mesa having a single mesa width of 5 micrometers. The quantum cascade laser CV has a mesa height of 6.8 micrometers.

Structures of the quantum cascade lasers DV and CV

Semiconductor supporting base: n-type InP

Upper and lower cladding layers; n-type InP

Core layer: GaInAs/AlInAs superlattice layer

Diffraction grating layer: n-type GaInAs

Contact layer: n-type GaInAs

Semiconductor embedding region: Fe-doped InP

The oscillation wavelength is 7.365 micrometers. The core layer has a thickness of 2.7 micrometers.

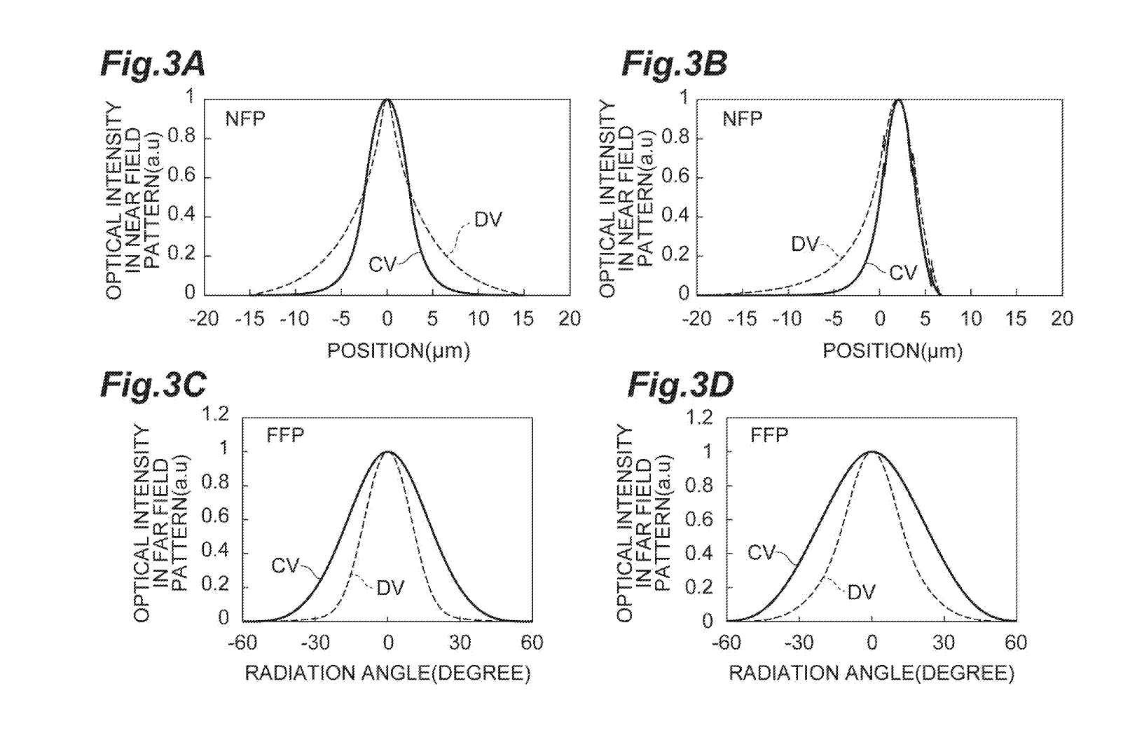

FIGS. 3A and 3B are graphs each showing the near-field patterns of the quantum cascade lasers DV and CV (at a wavelength of 7.365 micrometers). FIGS. 3C and 3D are graphs each showing the far-field patterns of the quantum cascade lasers DV and CV (at a wavelength of 7.365 micrometers).

The quantum cascade lasers DV and CV exhibit the near-field patterns (NFP) shown in FIGS. 3A and 3B. In FIG. 3A, the ordinate axis indicates the normalized relative intensity of light, and the abscissa axis indicates the coordinate in the transverse direction (the origin is on the center axis of the semiconductor mesa, and the positive axis goes to the right and the negative axis goes to the left). In FIG. 3B, the ordinate axis indicates the normalized relative intensity of light, and the abscissa axis indicates the coordinates in the longitudinal direction (the origin is on the interface between the epi-region and the supporting base region, i.e., at the level of the principal face 13a, and the positive axis goes to the epi-region and the negative axis goes to the supporting base region.

Referring to FIG. 3A, the quantum cascade lasers DV and CV each have an approximately symmetric near-field pattern (the light intensity profile, taken in the horizontal direction, at a position close to the emitting end face) with slopes on both sides of the peak of the near-field pattern. The quantum cascade laser DV makes its peak sharper than that of the quantum cascade laser CV and its slopes wider than that of the quantum cascade laser CV.

Referring to FIG. 3B, the quantum cascade lasers DV and CV each have a non-symmetric-shaped near field pattern (the light intensity profile, taken in the vertical direction, at a position close to the emitting end face), which has a tail on the lower side, and the quantum cascade laser DV makes the tail of the near-field pattern longer than that of the quantum cascade laser CV.

The quantum cascade lasers DV and CV exhibit the far-field patterns (FFP) shown in FIGS. 3C and 3D. In FIG. 3C, the ordinate axis indicates the normalized relative intensity of light, and the abscissa axis indicates the angle in the transverse direction (the origin is on the waveguide axis of the semiconductor mesa. In FIG. 3D, the ordinate axis indicates the normalized relative intensity of light, and the abscissa axis indicates the angle in the longitudinal direction (the origin is on the waveguide axis).

Referring to FIG. 3C, the quantum cascade lasers DV and CV each have a far-field pattern (the light intensity profile, taken in the horizontal direction, at a position distant from the emitting end face) with slopes on both sides of the peak, and the quantum cascade laser DV makes the far-field pattern narrower than that of the quantum cascade laser CV.

Referring to FIG. 3D, the quantum cascade lasers DV and CV each have a far-field pattern (the light intensity profile, taken in the vertical direction, at a position distant from the emitting end face), which has slopes on the both sides of the peak, and the quantum cascade laser DV makes the far-field pattern narrower than that of the quantum cascade laser CV.

Exemplary values of full width at half maximum (FWHM) in the respective far-field patterns are shown below.

Quantum cascade laser CV

Horizontal radiation angle: 38 degrees

Vertical radiation angle: 49 degrees

Quantum cascade laser DV

Horizontal radiation angle: 22 degrees

Vertical radiation angle: 26 degrees

These values indicate that the quantum cascade laser DV makes both the horizontal and vertical beam radiation angles smaller than those of the quantum cascade laser CV.

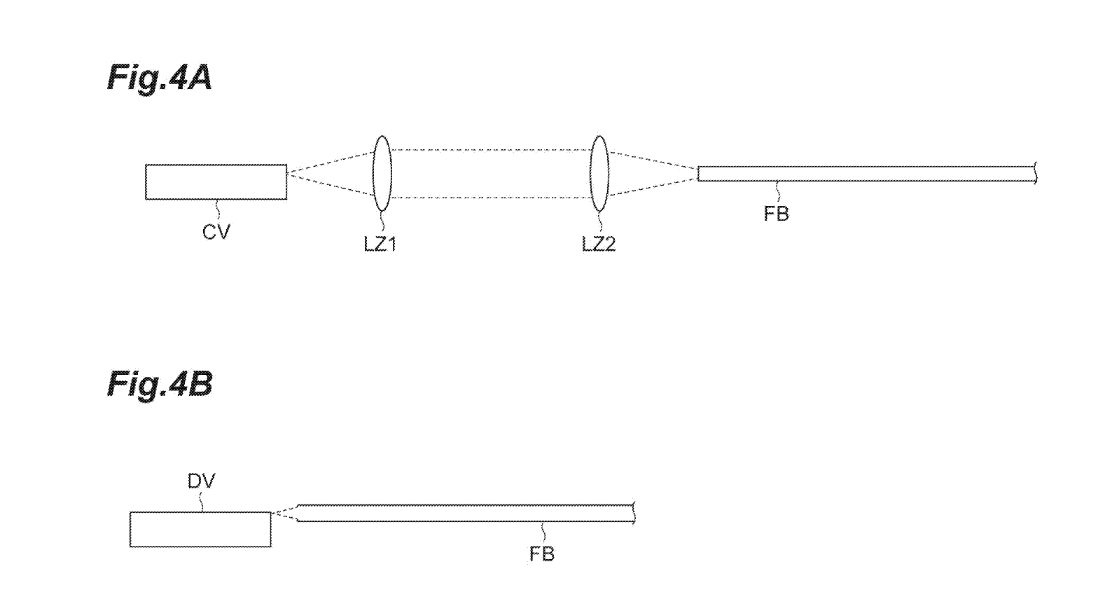

FIG. 4A is a schematic view showing the optical coupling between the quantum cascade laser CV and the optical waveguide structure FB. FIG. 4B is a schematic view showing the optical coupling between the quantum cascade laser DV and the optical waveguide structure FB.

The quantum cascade laser CV provides the far-field pattern with a width of the profile larger than that of the quantum cascade laser DV, but the quantum cascade laser DV provides the near-field pattern with a width of the profile larger than that of the quantum cascade laser CV, which shows that these magnitude relationships are in the inverse order. This inversion in magnitude indicates that the quantum cascade laser DV can provide the far-field pattern with a smaller radiation angle to facilitate the direct coupling of the quantum cascade laser DV with an optical waveguide structure FB, as shown in FIG. 4A, leading to a desired optical coupling therebetween.

The quantum cascade laser CV with a larger radiation angle in the far-field pattern uses the two lenses (LZ1 and LZ2) to be coupled to the optical waveguide structure FB, as shown in FIG. 4A, in order to obtain a desired optical coupling therebetween.

The quantum cascade laser 11 (11b to 11k) can be optically coupled to an external optical component, such as an optical waveguide, without lenses (which is made of expensive material, such as ZnSe, ZnS, and Ge) in mid-infrared and infrared wavelengths.

As shown in part (a) of FIG. 1, the quantum cascade laser 11 (11b to 11k) is provided with the laser structure 23. The laser structure 23 includes the semiconductor mesa 21, the supporting base 13, and the high specific-resistance semiconductor region 25. The second mesa portion 21b has a mesa width smaller than that of the first mesa portion 21a of a substantially constant mesa width. Specifically, the first mesa portion 21a is provided with the n-type lower cladding layer 22h (in the lower conductive semiconductor layer 22d), the core layer 22a (in the light emitting layer), and the diffraction grating layers 22e, the n-type upper cladding layer 22g and the n-type contact layer 22f (in the upper conductive semiconductor layer 22c). The second mesa portion 21b specifically is provided with, in addition to these semiconductor layers, the high specific-resistance semiconductor region 25. The second mesa portion 21b is different from the first mesa portion 21a in both the mesa width and the presence or absence of a high-specific resistance semiconductor region 25. In the present example, the quantum cascade laser 11 (11b to 11k) has an optical cavity, which includes the first and second end faces 19a and 19b, and emits lasing light from the second end face 19b. The lower and upper cladding layers 22h and 22g have the same conductivity type (for example, n-type). One of the first and second electrodes 15 and 17, for example, the first electrode 15 functions as an anode electrode, and the other electrode, for example, the second electrode 17, functions as a cathode electrode. These electrodes receive a voltage thereacross applied to the quantum cascade laser 11 (11b to 11k) in a range of, for example, about 10 to 15 volts.

A description will be given of semiconductors in the quantum cascade laser 11 (11b to 11k).

The supporting base 13 has a good electrical conductivity and may include, for example, an n-type InP wafer. The wafer of n-type InP allows the quantum cascade laser 11 (11b to 11k) to use electrons as carriers of current. A mid-infrared emission quantum cascade laser can be made of semiconductor layers having lattice constants close to or the same as the lattice constant of InP. The use of InP wafers facilitates the crystal growth of the semiconductor layers for the mid-infrared quantum cascade laser (having an emission wavelength of 3 to 20 micrometers).

Each of the upper and lower cladding layers 22g and 22h in the conductive semiconductor region 22b may include n-type InP. InP is a binary crystal, which enables good crystal growth on InP wafers. Moreover, InP has the highest heat conductivity among III-V compound semiconductor materials usable for mid-infrared quantum cascade lasers. The cladding layers of InP can provide the quantum cascade laser with a high heat dissipation performance allowing good temperature characteristics.

If necessary, the quantum cascade laser may be provided with the lower conductive semiconductor layer 22d, specifically the lower cladding layer 22h. The supporting base of InP is transparent to mid-infrared light, and can be used as a lower cladding region. The supporting base made of semiconductor works as cladding.

The core layer 22a is provided with the stacking of unit structures, each of which has an active layer and an injection layer, for example, in several tens of cycles. Specifically, the arrangement of unit structures contains multiple active layers and multiple injection layers, each of which includes one or more thin films for a quantum well layer having a thickness of several nanometers and one or more thin films for a barrier layer having a thickness of several nanometers, alternately arranged to form a superlattice. Each of the barrier layers has a bandgap higher than that of each of the quantum well layers.

Quantum cascade lasers utilize unipolar carriers, for example, electrons which transition between sub-bands in the conduction band to generate light. The active layer enables the optical transition of electrons from the upper to lower levels of the subband. The active layer on the low potential side is connected to the active layer on the high potential side via the injection layer therebetween in the core layer 22a. The injection layer between adjacent active layers allows the stream of electrons to flow from the high-potential active layer to the low-potential active layer. For example, the quantum well layers of GaInAs and GaInAsP and the barrier layers of AlInAs enable mid-infrared emission.

The high specific-resistance semiconductor region 25 includes undoped or semi-insulating semiconductor. These undoped and semi-insulating semiconductors each have a high specific resistance to electrons acting as carriers. In order to obtain the property of semi-insulating, a host semiconductor is doped with a transition metal, such as Fe, Ti, Cr, and Co. The addition of a transition metal to the host forms deep levels in the forbidden band which trap electrons in the host semiconductor to develop the property of semi-insulating. An exemplary dopant for semi-insulating semiconductors is iron (Fe). The addition of iron (Fe) to a host III-V compound semiconductor makes the III-V compound semiconductor highly-resistive, for example, 10⁵ Ωcm or more to electrons. Host semiconductors enabling un-doping and semi-insulating properties include III-V compound semiconductors, such as InP, GaInAs, AlInAs, GaInAsP, and AlGaInAs. These semiconductors are lattice-matched to InP of the supporting base and can be grown by a growth method, such as molecular beam epitaxy (MBE) and organometallic vapor phase epitaxy (OMVPE).

The quantum cascade laser 11 (11b to 11k) gives the optical cavity a type of Fabry-Perot or distributed feedback. If necessary, the quantum cascade laser may be provided with the diffraction grating layer 22e. The diffraction grating layer 22e enables a distributed feedback or a wavelength selection in the quantum cascade laser to demonstrate single mode operation. In the present example, the diffraction grating layer 22e is disposed between the core layer 22a and the upper cladding layer 22g of the upper conductive semiconductor layer 22c. The diffraction grating layer 22e has a structure, enabling a periodic refractive index distribution extending in the direction of the first axis Ax1, at the interface between the diffraction grating layer 22e and the upper cladding layer 22g of the upper conductive semiconductor layer 22c. This refractive index distribution structure enables selective feedback of laser light, propagating through the semiconductor mesa 21, at a specific wavelength associated with the grating period. Specifically, the distribution structure of refractive index has a period RMD as shown in FIG. 2D, and the period RMD defines the Bragg wavelength. The diffraction grating layer 22e provides the quantum cascade laser with a distributed feedback structure to enable good single mode oscillation. The diffraction grating layer 22e may be made of semiconductor, for example GaInAs, having a high refractive index, thereby providing the quantum cascade laser 11 with a large coupling coefficient. The diffraction grating layer 22e may include, for example, an n-type or undoped semiconductor.

If necessary, the quantum cascade laser may be provided with the contact layer 22f. In the present example, the contact layer 22f is disposed between the first electrode 15 and the upper cladding layer 22g of the upper conductive semiconductor layer 22c. The contact layer 22f is made of semiconductor, which has a small bandgap and is lattice-matched to InP, for example, GaInAs, and GaInAs enables good ohmic contact with the laser structure of the quantum cascade laser 11.

The semiconductor embedding region 29 includes an undoped or semi-insulating semiconductor. The undoped and semi-insulating semiconductors each have a high specific resistance to electrons acting as carriers. In order to provide a host semiconductor with the property of semi-insulating, the host semiconductor is doped with a transition metal, such as Fe, Ti, Cr and Co. An exemplary dopant enabling semi-insulating semiconductors is iron (Fe). The addition of iron (Fe) to III-V compound semiconductor makes, highly resistive, the III-V compound semiconductor thus doped, which has, for example, 10⁵ Ωcm or more to electrons. The semiconductor embedding region 29 may use undoped semiconductors and the host III-V compound semiconductor for semi-insulation includes semiconductor, such as InP, GaInAs, AlInAs, GaInAsP, and AlGaInAs.

If necessary, the quantum cascade laser may include a light confinement region, which is disposed either or both between the core layer 22a and the lower cladding layer 22h of the lower conductive semiconductor layer 22d and between the core layer 22a and the upper cladding layer 22g of the upper conductive semiconductor layer 22c. The light confinement region is used to enhance optical confinement of the guided light propagating in the core layer 22a, and can confine carriers into the core layer 22a. The light confinement region may include a high refractive index material, for example, undoped or n-type GaInAs, which can be lattice-matched to the supporting base of InP.

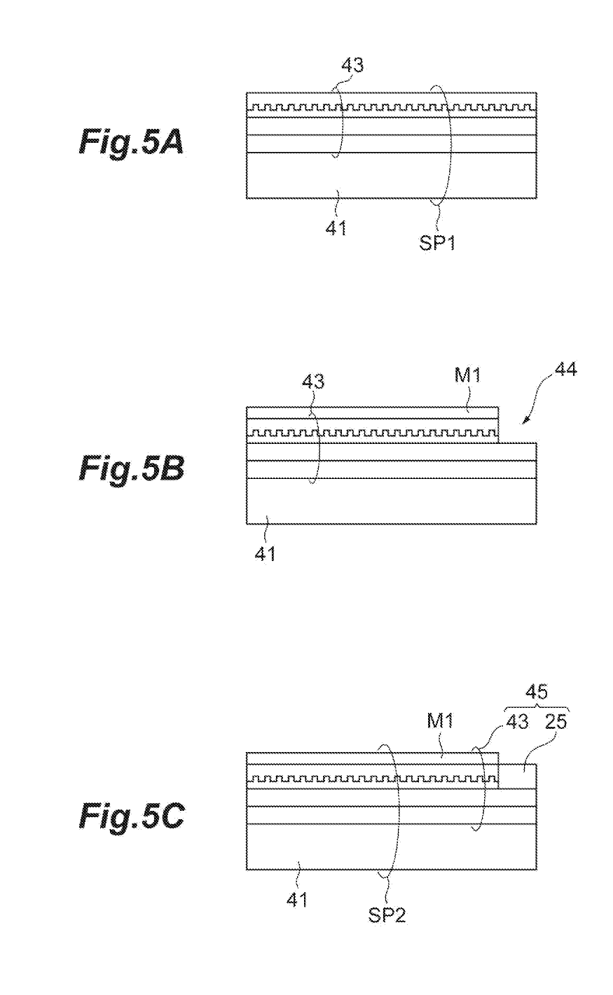

A description will be given of a method for fabricating the quantum cascade laser with reference to FIGS. 5A to 5C, FIGS. 6A to 6C, and FIGS. 7A to 7E. Where possible, reference numerals in the above description given with reference to FIG. 1, FIGS. 2A to 2C, and FIGS. 3A to 3D are also used in the following description.

The method includes a step for preparing a first substrate product SP1 as shown in FIG. 5A. The first substrate product SP1 includes a growth substrate 41 and a semiconductor laminate 43. The semiconductor laminate 43 includes semiconductor layers for the lower cladding layer 22h of the lower conductive semiconductor layer 22d, the core layer 22a, the diffraction grating layer 22e, and the lower portion of the upper cladding layer 22g of the upper conductive semiconductor layer 22c. The semiconductor laminate 43 is grown on the growth substrate 41.

The method includes the next step for forming an insulating mask M1, made of inorganic insulating material, on the first substrate product SP1 by photolithography and etching, as shown in FIG. 5B. The mask M1 has a strip opening. The semiconductor laminate 43 is etched with the mask M1 to form a recess 44, which reaches the semiconductor layer for the core layer in the semiconductor laminate 43.

Then, the method includes the next step for growing a semiconductor layer for the high specific-resistance semiconductor region 25 as shown in FIG. 5C. Specifically, the mask M1 is still left on the semiconductor laminate 43 after the etching, and the mask M1 is used to selectively grow the semiconductor layer for the high specific-resistance semiconductor region 25, thereby filling the strip-shaped recess 44 with the high specific-resistance semiconductor region 25, so that a second substrate product SP2 is obtained which has a semiconductor laminate 45 including both the semiconductor laminate 43 and the semiconductor layer (25) thus selectively grown.

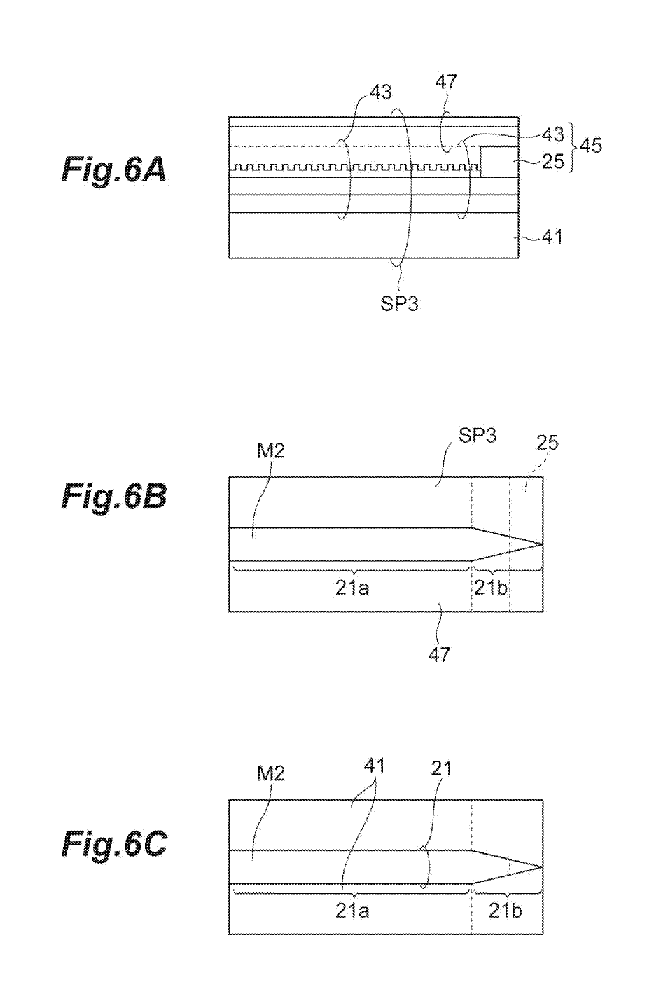

The method includes the next step for removing the mask M1 after the regrowth and then growing semiconductor layers, as shown in FIG. 6A, for the upper portion of the upper cladding layer 22g and the contact layer on the entire surface of the second substrate product SP2, thereby forming a third substrate product SP3.

The method includes the next step for forming an insulator mask M2, made of an inorganic insulating material, on the third substrate product SP3 as shown in FIG. 6B. The insulating mask M2 defines the respective shapes of the first mesa portion 21a and the second mesa portion 21b in the semiconductor mesa 21.

The method includes the next step for etching the growth substrate 41 and the semiconductor laminate 45 with the mask M2 to form the semiconductor mesa 21 as shown in FIG. 6C. The mask M2 is not removed after the etching.

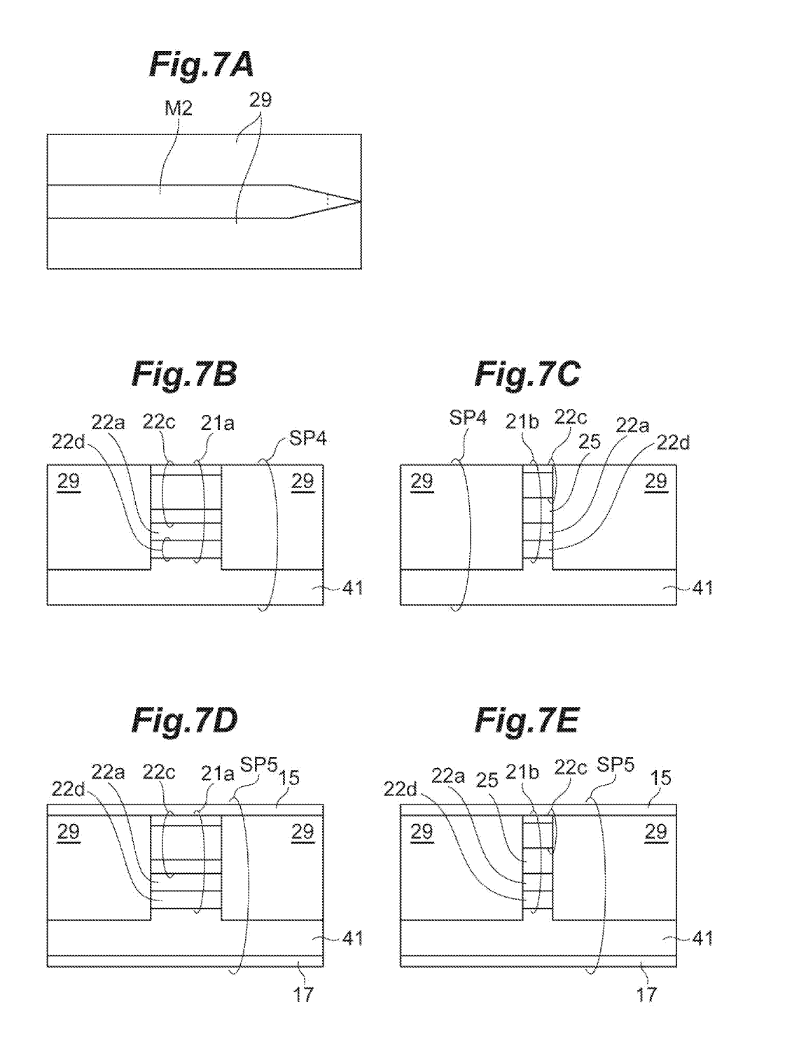

The method includes the next step for growing semiconductor for the semiconductor embedding region 29 with the mask M2, as shown in FIG. 7A, to embed the semiconductor mesa 21 with the semiconductor embedding region 29.

The method includes the next step for removing the mask M2 to obtain a fourth substrate product SP4 as shown in FIGS. 7B and 7C.

The method includes the next step for forming electrodes for the quantum cascade laser, such as the first electrode 15 and the second electrode 17, on the fourth substrate product SP4 as shown in FIGS. 7D and 7E, thereby producing the fifth substrate product SP5. If necessary, the insulating film 27 may be formed prior to the formation of the first electrode 15.

The above steps bring the quantum cascade laser 11b to completion. The quantum cascade laser 11 (11c to 11k) is formed in accordance with the pattern of the mask M1, the height of the mesa determined by the duration of etching with the mask M1, and the regrowth of embedding semiconductor after the etching.

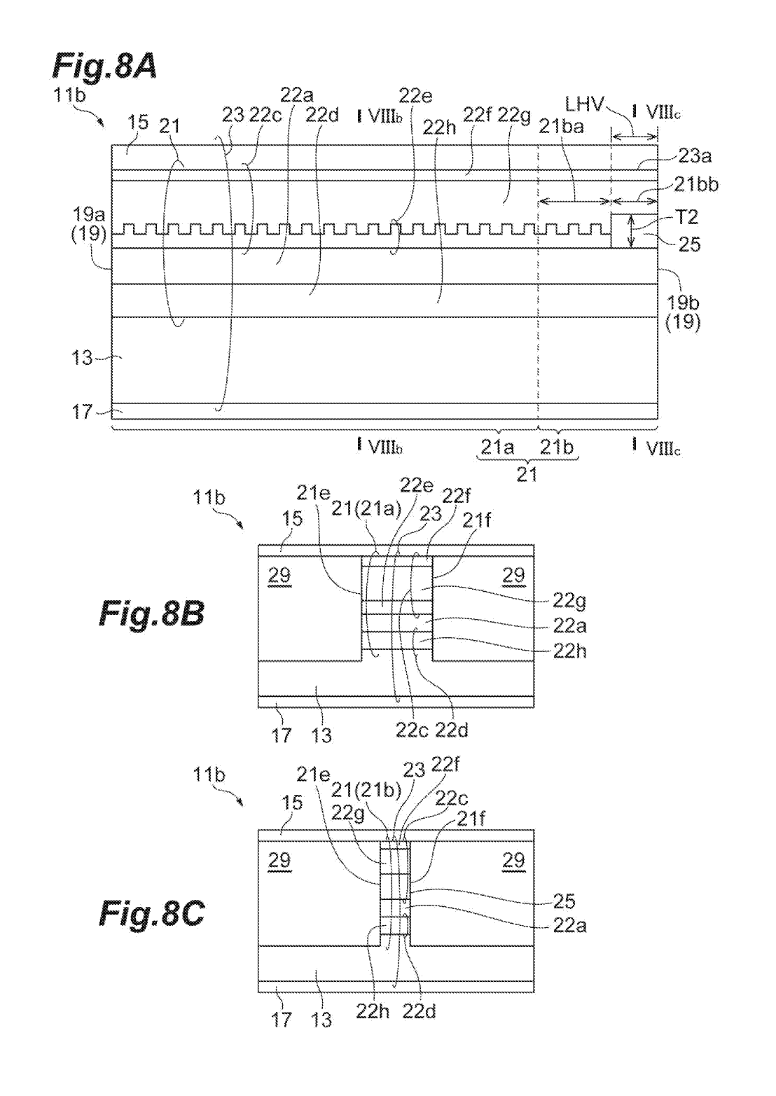

Subsequently, a description will be given of a method for fabricating the quantum cascade laser 11 (11b to 11f) with reference to FIGS. 8A, 8B and 8C, FIGS. 9A, 9B and 9C, FIGS. 10A, 10B and 10C, FIGS. 11A, 11B and 11C, FIGS. 12A, 12B and 12C, FIGS. 13A and 13B, FIGS. 14A and 14B and FIG. 15. The high specific-resistance semiconductor region 25 is formed in the second mesa portion 21b in the vicinity of the second end face 19b to terminate a part or the whole of the current path between the first electrode 15 and the second electrode 17 in the second mesa portion 21b. In the example, the high specific-resistance semiconductor region 25 may be disposed across the second mesa portion 21b so as to extend from one side face 21e of the semiconductor mesa 21 to the other side face 21f, thereby isolating conductive semiconductor in the second mesa portion 21b from that in the first mesa portion 21a.

A description will be given of fabricating the quantum cascade laser 11 (11b to 11f, and 11g). Specifically, the second mesa portion 21b has a first portion 21ba and a second portion 21bb, which are arranged in the direction of the first axis Ax1. The first portion 21ba includes a conductive semiconductor (for example, the core layer 22a, the upper conductive semiconductor layer 22c, and the lower conductive semiconductor layer 22d) which reaches the first mesa portion 21a. The second portion 21bb extends from the first portion 21ba to the second end face 19b. The second portion 21bb includes the high specific-resistance semiconductor region 25, and the high specific-resistance semiconductor region 25 reaches the second end face 19b. The second portion 21bb is separated away from the first mesa portion 21a by the first portion 21ba, which also separates the high specific-resistance semiconductor region 25 away from the first mesa portion 21a.

Further, the quantum cascade laser 11 (11b to 11f) provides the first electrode 15 with the end portion 15a, as shown in part (g) of FIG. 1, located on not the second portion 21bb but the first portion 21ba.

FIG. 8A is a cross sectional view, taken along line IId-IId or line I-I shown in FIG. 1, showing the quantum cascade laser 11b. FIG. 8B is a cross sectional view taken along line VIIIb-VIIIb shown in FIG. 8A, and FIG. 8C is a sectional view taken along line VIIIc-VIIIc shown in FIG. 8A.

The quantum cascade laser 11b is provided with the core layer 22a and the lower conductive semiconductor layer 22d, which extends from the first end face 19a to the second end face 19b. The upper conductive semiconductor layer 22c separates the high specific-resistance semiconductor region 25 away from the first end face 19a, and the high specific-resistance semiconductor region 25 reaches the second end face 19b. The diffraction grating layer 22e in the upper conductive semiconductor layer 22c extends from the first end face 19a to the high specific-resistance semiconductor region 25, and is separated away from the second end face 19b by the high specific-resistance semiconductor region 25. The high specific-resistance semiconductor region 25 is disposed between the core layer 22a and the upper conductive semiconductor layer 22c, leading to making contact with the core layer 22a.

The high specific-resistance semiconductor region 25 has a thickness (T2), and the thickness (T2) can be, for example, 100 nm or more. The high specific-resistance semiconductor region 25 is effective in reducing the amount of current flowing in the vicinity of the second mesa portion 21b, in particular, along the second end face 19b, leading to the reduction in the current density in the vicinity of the second end face 19b.

The quantum cascade laser 11b to 11g each may provide the semiconductor mesa 21 with the high specific-resistance semiconductor region 25 of a length (LHV) extending from the second end face 19b, and the length (LHV) may be, for example, 10 μm or more. The high specific-resistance semiconductor region 25 can reduce the amount of current flowing in the vicinity of the second mesa portion 21b, in particular, along the second end face 19b, leading to the reduction in the current density in the vicinity of the second end face 19b.

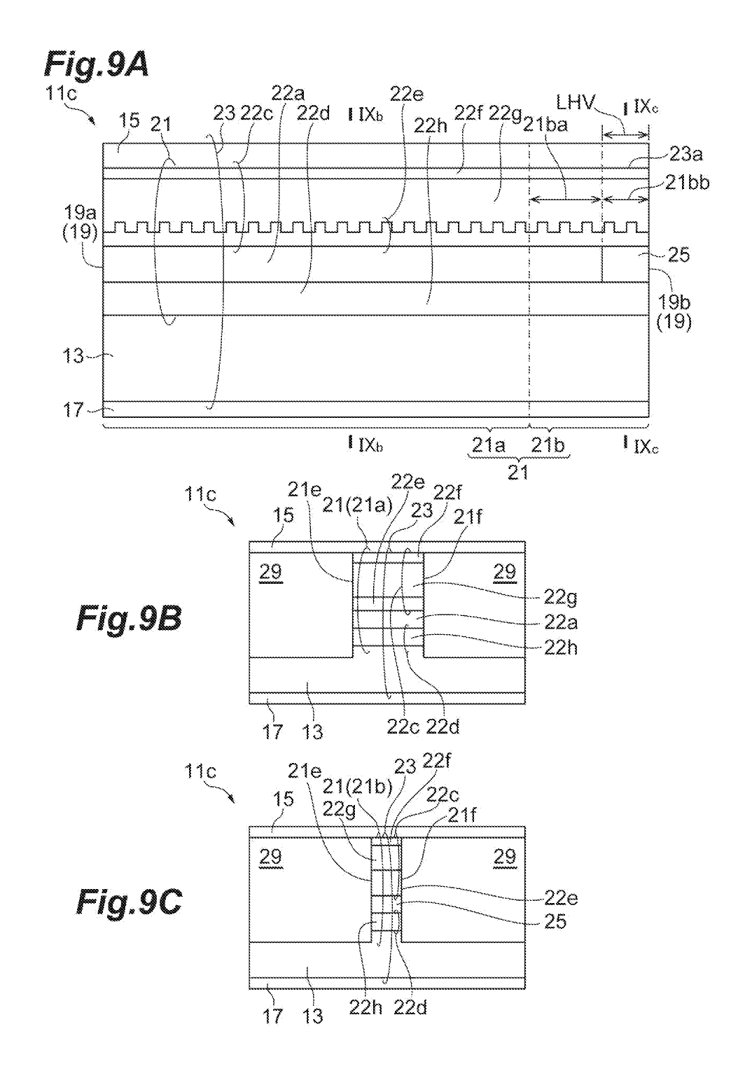

FIG. 9A is a cross sectional view, taken along line IId-IId or I-I shown in FIG. 1, showing the quantum cascade laser 11c. FIG. 9B is a cross sectional view taken along line IXb-IXb shown in FIG. 9A, and FIG. 9C is a cross sectional view taken along line IXc-IXc shown in FIG. 9A.

The quantum cascade laser 11c may be provided with the upper conductive semiconductor layer 22c and the lower conductive semiconductor layer 22d, which extend from the first end face 19a to the second end face 19b. The high specific-resistance semiconductor region 25 may have substantially the same thickness as the core layer 22a.

The high specific-resistance semiconductor region 25 reaches the second end face 19b, but is separated away from the first end face 19a by the core layer 22a, so that the high specific-resistance semiconductor region 25 can prevent the current from flowing in the vicinity of the second mesa portion 21b, more specifically along the second end face 19b, leading to the reduction in the current density in the vicinity of the second end face 19b.

The high specific-resistance semiconductor region 25 can extend from the second end face 19b and terminates in the semiconductor mesa 21 within a length (LHV) from the second end face 19b. The high specific-resistance semiconductor region 25 may be provided with the length (LHV) taken from the second end face 19b. The high specific-resistance semiconductor region 25 can prevent the current from flowing in the vicinity of the second mesa portion 21b, in particular, along the second end face 19b, leading to the reduction in the current density in the vicinity of the second end face 19b.

The method for fabricating the quantum cascade laser 11c includes the following steps: growing semiconductor layers for the lower conductive semiconductor layer 22d and the core layer 22a; partially etching the semiconductor layer for the core layer 22a with a mask to form an opening, which extends to the semiconductor layer for the lower conductive semiconductor layer 22d. in the semiconductor layer for the core layer 22a; re-growing a semiconductor layer for the high specific-resistance semiconductor region 25 with the mask to fill the opening with the semiconductor; after the regrowth, removing the mask and then growing a semiconductor layer for the upper conductive semiconductor layer 22c to form the first substrate product SP1. The application of the previously described processes to the first substrate product SP1 brings the quantum cascade laser 11c to completion.

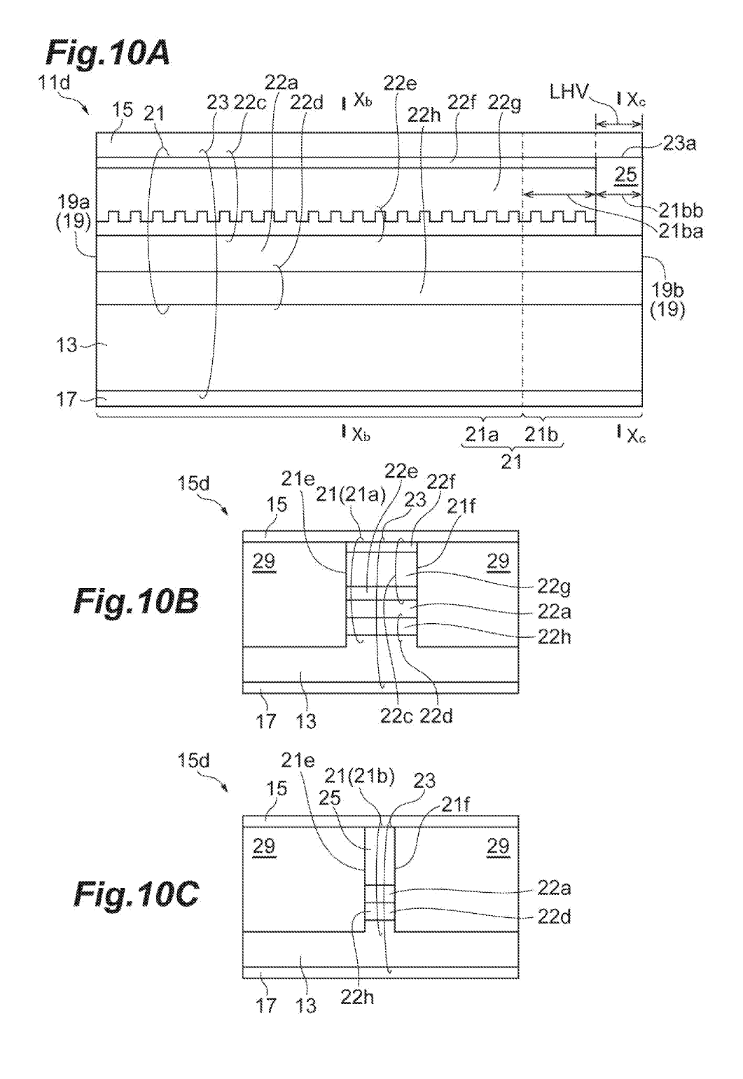

FIG. 10A is a cross sectional view taken along lines IId-IId and I-I shown in FIG. 1, showing the quantum cascade laser 11d. FIG. 10B is a cross sectional view taken along line Xb-Xb shown in FIG. 10A, and FIG. 10C is a cross sectional view taken along line Xc-Xc shown in FIG. 10A.

The quantum cascade laser 11d may be provided with the core layer 22a and the lower conductive semiconductor layer 22d, which extend from the first end face 19a to the second end face 19b. The high specific-resistance semiconductor region 25 reaches the second end face 19b, but is separated away from the first end face 19a by the upper conductive semiconductor layer 22c. The upper conductive semiconductor layer 22c extends from the first end face 19a to the high specific-resistance semiconductor region 25 and is separated from the second end face 19b by the high specific-resistance semiconductor region 25. The high specific-resistance semiconductor region 25 extends from the upper face of the core layer 22a to the upper face 23a of the laser structure 23. In the example, the high specific-resistance semiconductor region 25 is provided with the top and bottom faces, which make contact with the first electrode 15 and the core layer 22a, respectively.

The high specific-resistance semiconductor region 25 may have substantially the same thickness as that of the upper conductive semiconductor layer 22c. The high specific-resistance semiconductor region 25 can prevent the amount of current from flowing in the vicinity of the second mesa portion 21b, in particular, along the second end face 19b, leading to the reduction in the current density in the vicinity of the second end face 19b.

The high specific-resistance semiconductor region 25 may extend from the second end face 19b and terminates in the semiconductor mesa 21 within a length (LHV) taken from the second end face 19b, and may be provided with the length (LHV). The high specific-resistance semiconductor region 25 can prevent the current from flowing in the vicinity of the second mesa portion 21b, in particular along the second end face 19b, leading to the reduction in the current density in the vicinity of the second end face 19b.

The method for fabricating the quantum cascade laser 11d may include the following steps: growing semiconductor layers for the lower conductive semiconductor layer 22d, the core layer 22a, and the upper conductive semiconductor layer 22c to form an epi-product; forming a mask on the epi-product and then partially etching the semiconductor layer for the upper conductive semiconductor layer 22c in the epi-product with the mask to form, in the semiconductor layer for the upper conductive semiconductor layer 22c, an opening to the semiconductor layer for the core layer 22a; re-growing a semiconductor layer for the high specific-resistance semiconductor region 25 in the opening with the mask; and removing the mask after regrowth to form a first substrate product SP1. The application of the previously described processes to the first substrate product SP1 brings the quantum cascade laser 11d to completion/

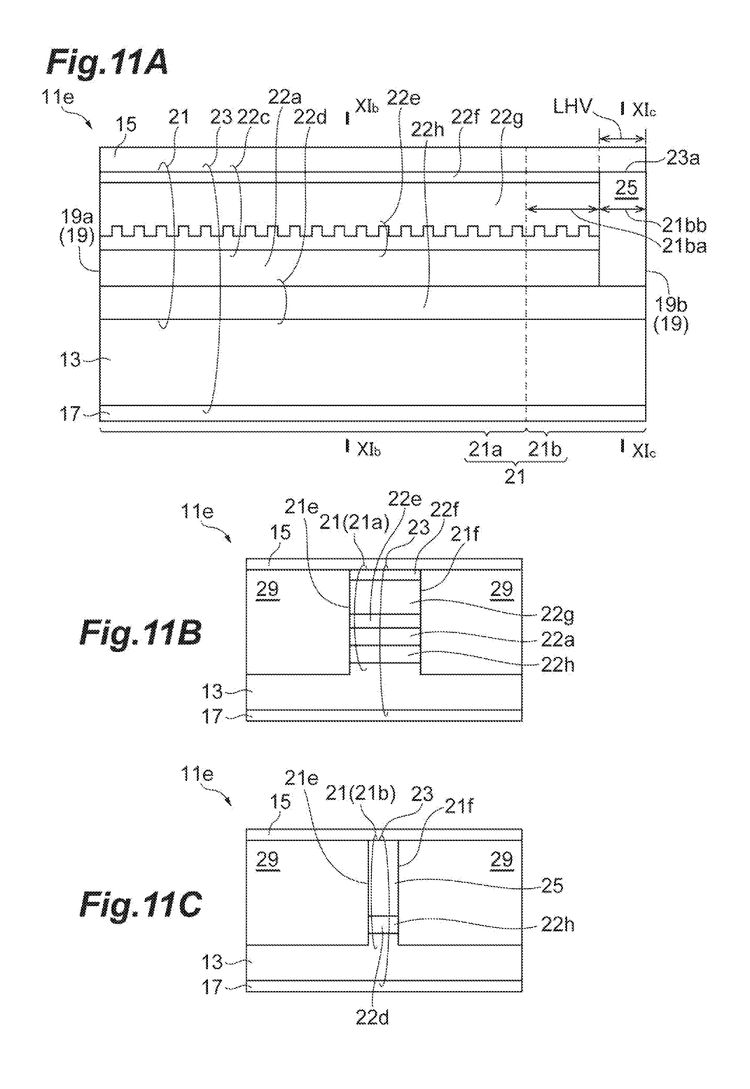

FIG. 11A is a cross sectional view taken along line IId-IId or line I-I shown in FIG. 1, showing the quantum cascade laser 11e. FIG. 11B is a cross sectional view taken along line XIb-XIb shown in FIG. 11A, and FIG. 11C is a cross sectional view taken along line XIc-XIc shown in FIG. 11A.

The quantum cascade laser 11e may be provided with the lower conductive semiconductor layer 22d, which extends from the first end face 19a to the second end face 19b. The high specific-resistance semiconductor region 25 reaches the second end face 19b, but is separated away from the first end face 19a by the core layer 22a and the upper conductive semiconductor layer 22c. The core layer 22a and the upper conductive semiconductor layer 22c extend from the first end face 19a to the high specific-resistance semiconductor region 25, and are separated away from the second end face 19b by the high specific-resistance semiconductor region 25. The high specific-resistance semiconductor region 25 extends from the top face 23a of the laser structure 23 to the lower conductive semiconductor layer 22d in the direction intersecting the principal face of the supporting base 13. In the present example, the high specific-resistance semiconductor region 25 has upper and lower faces, which are in contact with the lower conductive semiconductor layer 22d and the first electrode 15, respectively.

The high specific-resistance semiconductor region 25 may have substantially the same thickness as the sum of the thicknesses of the upper conductive semiconductor layer 22c and the core layer 22a. The high specific-resistance semiconductor region 25 can prevent the amount of current from flowing in the vicinity of the second mesa portion 21b, in particular along the second end face 19b, leading to the reduction in the current density in the vicinity of the second end face 19b.

The high specific-resistance semiconductor region 25 can extend from the second end face 19b and terminates within a length (LHV) taken from the second end face 19b. The high specific-resistance semiconductor region 25 may be provided with the length (LHV) in the semiconductor mesa 21. The high specific-resistance semiconductor region 25 can prevent the amount of current from flowing in the vicinity of the second mesa portion 21b, in particular along the second end face 19b, leading to the reduction in the current density in the vicinity of the second end face 19b.

The method for fabricating the quantum cascade laser 11e may include the following steps: growing semiconductor layers for the lower conductive semiconductor layer 22d, the core layer 22a, and the upper conductive semiconductor layer 22c to form an epi-product; forming a mask on the epi-product and then partially etching, with the mask, the semiconductor layers for the upper conductive semiconductor layer 22c and the core layer 22a in the epi-product to form, in the semiconductor layers for the upper conductive semiconductor layer 22c and the core layer 22a, an opening to the semiconductor layers for the lower conductive semiconductor layer 22d; re-growing a semiconductor layer for the high specific-resistance semiconductor region 25 in the opening with the mask to fill the opening with the semiconductor layer; and after the regrowth, removing the mask to form a first substrate product SP1. The application of the previously described processes to the first substrate product SP1 bring the quantum cascade laser 11e to completion.

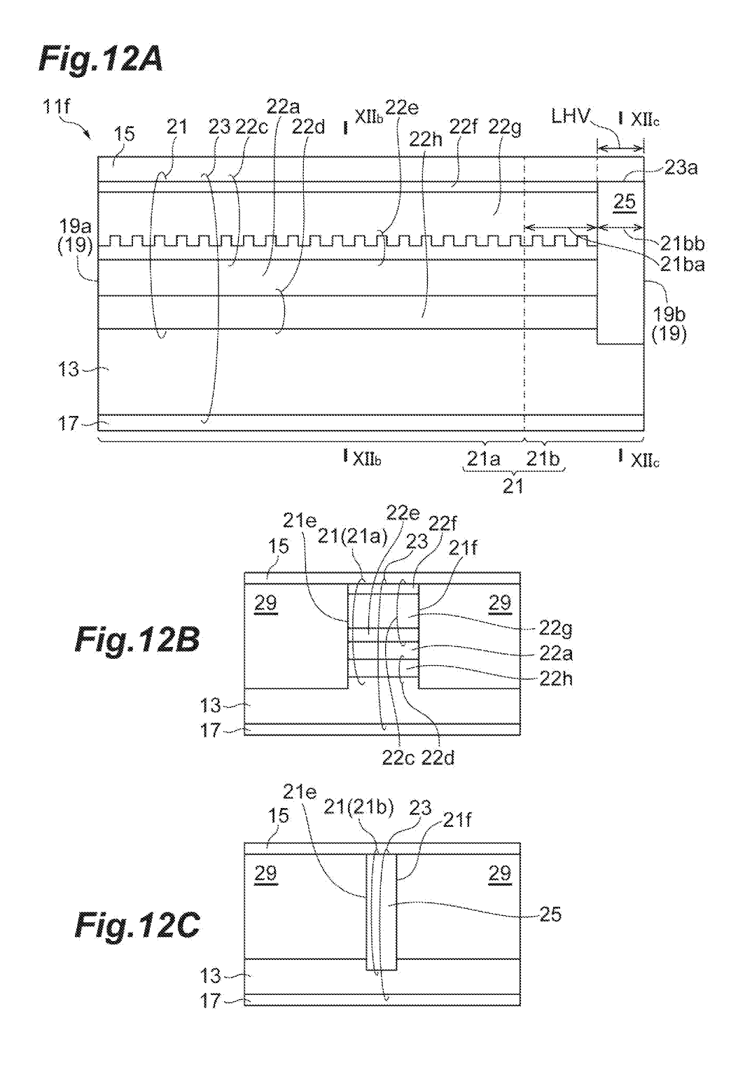

FIG. 12A is a cross sectional view, taken along line IId-IId and line I-I shown in FIG. 1, showing the quantum cascade laser 11f. FIG. 12B is a cross sectional view taken along line XIIb-XIIb shown in FIG. 12A, and FIG. 12C is a cross sectional view taken along line XIIc-XIIc shown in FIG. 12A.

The quantum cascade laser 11f may be provided with the high specific-resistance semiconductor region 25, which is separated from the first end face 19a by the lower conductive semiconductor layer 22d, the core layer 22a and the upper conductive semiconductor layer 22c and reaches the second end face 19b. The lower conductive semiconductor layer 22d, the core layer 22a and the upper conductive semiconductor layer 22c extend from the first end face 19a to abut against the high specific-resistance semiconductor region 25, and is separated from the second end face 19b by the high specific-resistance semiconductor region 25. In the example, the high specific-resistance semiconductor region 25 has a top face, which is in contact with the first electrode 15, and a bottom which abuts against the supporting base 13 to form an interface with the supporting base 13. The high specific-resistance semiconductor region 25 extends from the supporting base 13 in the direction intersecting the principal face of the supporting base 13 to reach the top face 23a of the laser structure 23.

The high specific-resistance semiconductor region 25 may have substantially the same as or greater than the sum of the thicknesses of the upper conductive semiconductor layer 22c, the core layer 22a, and the lower conductive semiconductor layer 22d. The high specific-resistance semiconductor region 25 can prevent the amount of current from flowing in the vicinity of the second mesa portion 21b, in particular along the second end face 19b, leading to the reduction in the current density in the vicinity of the second end face 19b.

The high specific-resistance semiconductor region 25 may extend from the second end face 19b and terminate in the semiconductor mesa 21, so that the high specific-resistance semiconductor region 25 has a length, taken from the second end face 19b, equal to or less than a length (LHV). The high specific-resistance semiconductor region 25 may be provided with the length (LHV) in the second mesa portion 21b. The high specific-resistance semiconductor region 25 can prevent the amount of current from flowing in the vicinity of the second end face 19b, in particular along the second end face 19b, leading to the reduction in the current density in the vicinity of the second end face 19b.

The method for fabricating the quantum cascade laser 11f includes the following steps: growing semiconductor layers for the lower conductive semiconductor layer 22d, the core layer 22a, and the upper conductive semiconductor layer 22c to form an epi-product; forming a mask on the epi-product and then partially etching semiconductor layers for the lower conductive semiconductor layer 22d, the core layer 22a, and the upper conductive semiconductor layer 22c in the epi-product with the mask to form an opening to the supporting base 13 in the epi-product, specifically the semiconductor layers for the lower conductive semiconductor layer 22d, the core layer 22a and the upper conductive semiconductor layer 22c; re-growing a semiconductor layer for high specific-resistance semiconductor region 25 with the mask to fill the opening with the semiconductor layer; after the regrowth, removing the mask to form a first substrate product SP1. The application of the previously described processes to the first substrate product SP1 brings the quantum cascade laser 11f to completion.

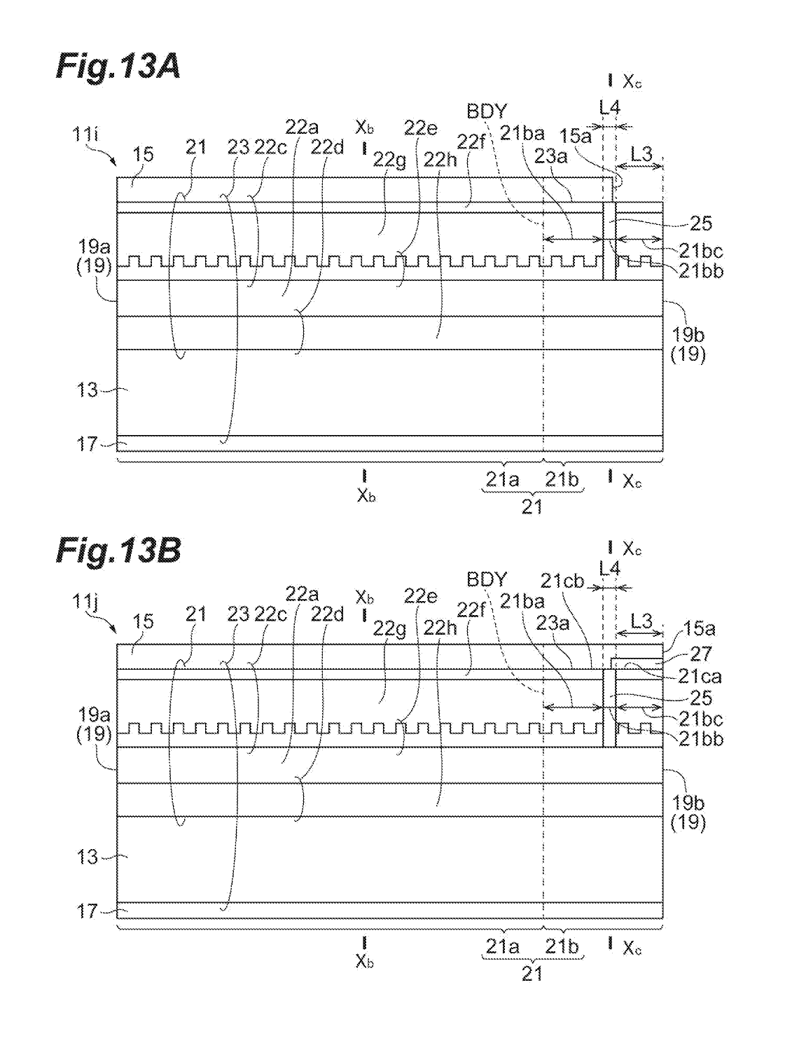

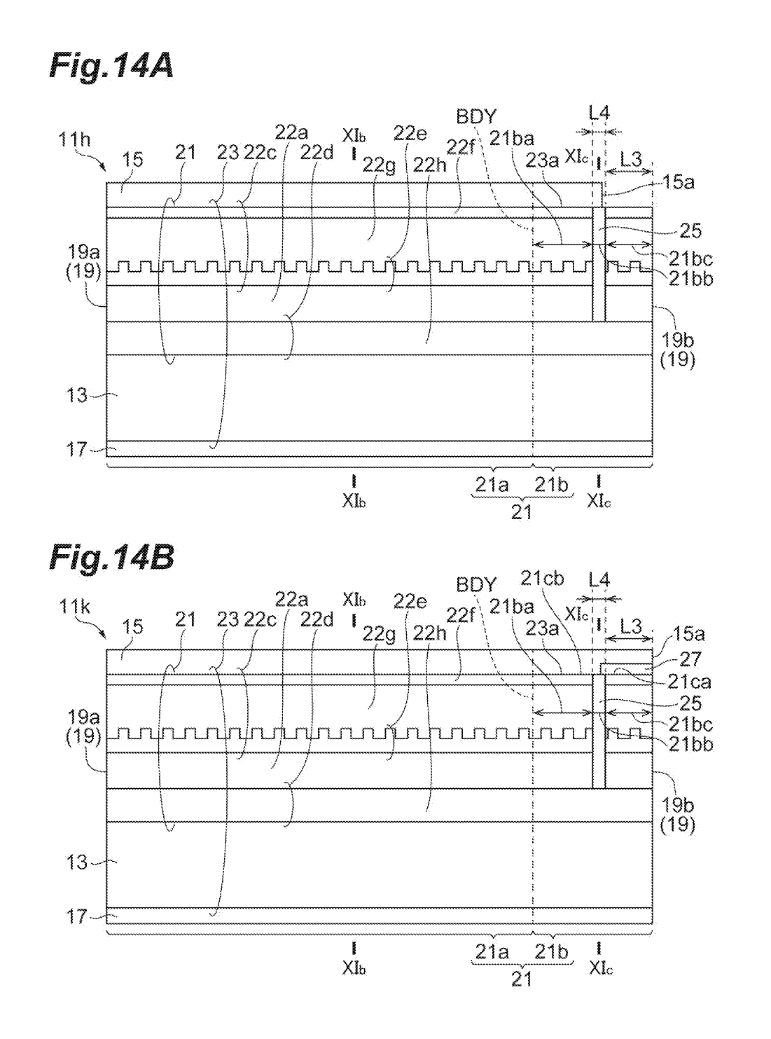

A description will be given of a method for fabricating the quantum cascade laser 11 (11h to 11k) with reference to FIGS. 13A and 13B and FIGS. 14A and 14B, which are cross sectional views taken along line IId-IId or I-I shown in FIG. 1. The quantum cascade laser 11 (11h to 11k) is provided with the high specific-resistance semiconductor region 25, which is disposed away from the first and second end faces 19a and 19b and extends from the top face of the laser structure 23 in the direction from the semiconductor mesa 21 to the supporting base 13. The high specific-resistance semiconductor region 25 is disposed across the semiconductor mesa 21 so as to extend from one side face 21e of the semiconductor mesa 21 to the other side face 21f in the second mesa portion 21b, so that the high specific-resistance semiconductor region 25 divides the second mesa portion 21b into two sections, one of which is connected to the first mesa portion 21a and makes contact with the first electrode 15 and the other of which is located between the high specific-resistance semiconductor region 25 and the second end face 19b. The other section is not connected to the first mesa portion 21a and does not make contact with the first electrode 15.

The high specific-resistance semiconductor region 25, which is disposed across the semiconductor mesa 21 so as to extend from one side face 21e of the semiconductor mesa 21 to the other side face 21f, terminates a part or all of the conductive semiconductor layers in the semiconductor mesa 21. Specifically, the high specific-resistance semiconductor region 25 separates a part or all of the lower conductive semiconductor layer 22d, the core layer 22a, and the upper conductive semiconductor layer 22c, which extends from the high specific-resistance semiconductor region 25 to the second end face 19b, from those extending from the high-specific resistance semiconductor region 25 to the first end face 19a.

Specifically, the second mesa portion 21b has a first part 21ba, a second part 21bb and a third part 21bc, which are arranged in the direction of the first axis Ax1. The first part 21ba is provided with conductive semiconductor (for example, the core layer 22a, the upper conductive semiconductor layer 22c, and the lower conductive semiconductor layer 22d), which reaches the first mesa portion 21a. The second part 21bb is provided with the high specific-resistance semiconductor region 25, which extends downward from the top face of the second mesa portion 21b. The third part 21bc is provided with conductive semiconductor (for example, the core layer 22a, the upper conductive semiconductor layer 22c, and the lower conductive semiconductor layer 22d), which reaches the second end face 19b.

The quantum cascade laser 11 (11h and 11k) is provided with the high specific-resistance semiconductor region 25, which reaches the lower conductive semiconductor layer 22d from the top face of the second mesa portion 21b in the second part 21bb.

The quantum cascade laser 11 (11i and 11j) is provided with the high specific-resistance semiconductor region 25, which extends downward from the top face of the second mesa portion 21b to reach the core layer 22a in the second part 21bb.

The first electrode 15 may be provided with the end 15a, which is positioned on the first part 21ba or the second part 21bb. The quantum cascade laser 11 (11h and 11i) is provided with the first electrode 15, which terminates in the second part 21bb, and the first electrode 15 has an end 15a away from the third part 21bc as shown in parts (h) and (i) of FIG. 1.

Referring to FIGS. 13A and 13B, the quantum cascade laser 11 (11i and 11j) may be provided with the high specific-resistance semiconductor region 25, which extends downward from the top face 23a of the laser structure 23 to penetrate through the upper conductive semiconductor layer 22c of the laser structure 23 to the core layer 22a, thereby terminating the upper conductive semiconductor layer 22c.

The high specific-resistance semiconductor region 25 separates the upper conductive semiconductor layer 22c, which extends from the high specific-resistance semiconductor region 25 to the second end face 19b, away from the upper conductive semiconductor layer 22c extending from the high specific-resistance semiconductor region 25 to the first end face 19a. The high specific-resistance semiconductor region 25 blocks carriers associated with the first electrode 15 to keep away from the vicinity of the second end face 19b. The high specific-resistance semiconductor region 25 can prevent the current from flowing in the vicinity of the second mesa portion 21b in the second mesa portion 21b, in particular along the second end face 19b, leading to the reduction in the current density in the vicinity of the second end face 19b.

Specifically, as shown in FIG. 13A, the quantum cascade laser 11 (11i) provides the first electrode 15 with the end 15a, which is disposed far from the second end face 19b, in particular, on the high specific-resistance semiconductor region 25 that forms the top face 23a of the laser structure 23.

Alternatively, as shown in FIG. 13B, the quantum cascade laser 11 (11j) may be provided with an insulating film 27, which extends from the second end face 19b on the top face 23a of the laser structure 23 and terminates on the high specific-resistance semiconductor region 25. The insulating film 27 is disposed from the high specific-resistance semiconductor region 25 to the second end face 19b on the top face of the semiconductor mesa 21e to cover the entire top face of the semiconductor mesa 21. The first electrode 15 is provided with the end 15a on the insulating film 27 and in the present example, reaches the second end face 19b. The insulating film 27 prevents the first electrode 15 from making contact with the second mesa portion 21b in the vicinity of the second end face 19b. The insulating film 27 may include dielectric material. such as SiO₂, SiON, SiN, alumina, BCB, and polyimide.

Referring to FIGS. 14A and 14B, the quantum cascade laser 11 (11h and 11jk) is provided with the high specific-resistance semiconductor region 25, which extends downward from the top face 23a of the laser structure 23 to the lower conductive semiconductor layer 22d, thereby terminating the upper conductive semiconductor layer 22c and the core layer 22a in the laser structure 23.

The high specific-resistance semiconductor region 25 can separate the upper conductive semiconductor layer 22c and the core layer 22a, which extends from the high specific-resistance semiconductor region 25 to the second end face 19b, away from those extending from the high specific-resistance semiconductor region 25 to the first end face 19a. The high specific-resistance semiconductor region 25 blocks the carriers associated with the first electrode 15 such that the carriers keep away from the vicinity of the second end face 19b. The high specific-resistance semiconductor region 25 can prevent the current from flowing in the vicinity of the second mesa portion 21b, in particular along the second end face 19 b, leading to the reduction in the current density in the vicinity of the second end face 19b.

Specifically, as shown in FIG. 14A, the quantum cascade laser 11 (11h) provides the first electrode 15 with the end 15a, which is separated away from the second end face 19b on the top face of the laser structure 23, in particular the high specific-resistance semiconductor region 25.

Alternatively, as shown in FIG. 14B, the quantum cascade laser 11 (11k) is provided with the insulating film 27, which extends from the second end face 19b and terminates on the high specific-resistance semiconductor region 25. The insulating film 27 is disposed on the top face of the semiconductor mesa 21 and extends from the second end face 19b to the high specific-resistance semiconductor region 25 to cover the face of the semiconductor mesa 21 therebetween. The first electrode 15 is provided with the end 15a, which is located on the insulating film 27. The insulating film 27 prevents the first electrode 15 from making contact with the second mesa portion 21b, in particular, in the vicinity of the second end face 19b.

The quantum cascade laser 11 (11h to 11k) is also provided with the high specific-resistance semiconductor region 25, which is away from the second end face 19b by the distance (L3), and the distance (L3) may be in the range of, for example, 10 to 100 micrometers. The high specific-resistance semiconductor region 25 has a width (L4) in the range of for example, 10 to 100 micrometers.

Referring to FIGS. 13A and 13B and FIGS. 14A and 14B, the laser structure 23 provides the top face 23a in the second mesa portion 21b with a first area 21ca and a second area 21cb, and the first and second areas 21ca and 21cb are arranged in the direction from the end face 19a to the second end face 19b. The first area 21ca extends from the second area 21cb to the second end face 19b. The second area 21cb extends from the first area 21ca to the boundary BDY. The high specific-resistance semiconductor region 25 extends downward in the direction from the top face of the second mesa portion 21b to the supporting base 13 at the boundary between the first and second areas 21ca and 21cb. The quantum cascade laser 11 is also provided with the insulating film 27, which is disposed on the second mesa portion 21b, in particular the first area 21ca, to be disposed between the first electrode 15 and the laser structure 23.

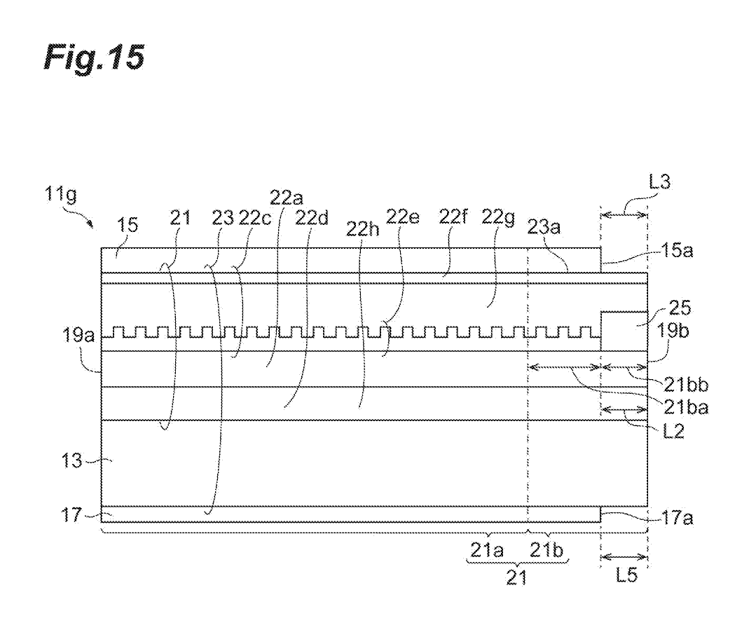

The quantum cascade laser 11 (11b to 11k) is provided with the first and second electrodes 15 and 17 having respective ends 15a and 17a, either or both of which may be away from the second end face 19b toward the first end face 19a. Referring to FIG. 15, the quantum cascade laser 11 (11g) provides both the first electrode 15 and the second electrode 17 with the ends 15a and 17a away from the second end face 19b. The distance (L3) from the second end face 19b to the first electrode 15 can be, for example, in the range of 10 to 100 micrometers, and the distance (L5) from the second end face 19b to the second electrode 17 can be, for example, in the range of 10 to 100 micrometers. Separating either or all of the first electrode 15 and the second electrode 17 from the second mesa portion 21b can control the amount of current flowing in the vicinity of the second mesa portion 21b, in particular flowing along the second end face 19b, leading to the reduction in the current density near the second end face 19b.

The quantum cascade laser 11, such as the quantum cascade laser 11 (11b to 11k), receives not only an operation voltage, for example 10 volts or more, allowing carriers in the core layer 22a to transition between sub-bands in the conduction band thereby emitting laser light, but also an operating current of several hundred milliamps, thereby causing the quantum cascade laser 11 to lase at a current density which is about two orders of magnitude larger than that of laser diodes for optical communication.

As seen from the above description, the high specific-resistance semiconductor region 25 can reduce the current density in the vicinity of the second end face 19b, thereby making, lower, the power applied to the vicinity of the second end face 19b. This results in that the reduction in the applied power suppresses the amount of heat generated in the end portion of the second mesa portion 21b close to the second end face 19b. The low power generation makes it possible for the quantum cascade laser 11 (11b to 11k) to be free from accidental failures, for example melting of the second end face 19b, which comes from the temperature rise caused by a large amount of accidental heat generation around the end portion 21c of the second mesa portion 21b. The quantum cascade laser 11 (11b to 11k) can reduce the occurrence of such failures to improve device reliabilities,

As seen from the above description, the present embodiment can provide a quantum cascade laser with a structure allowing both a desired angular divergence in optical emission and a desired current distribution around the emitting face.

Having described and illustrated the principle of the invention in a preferred embodiment thereof, it is appreciated by those having skill in the art that the invention can be modified in arrangement and detail without departing from such principles. We therefore claim all modifications and variations coining within the spirit and scope of the following claims.

What is claimed is:

1. A quantum cascade laser comprising:
a laser structure including a first end face, a second end face, a semiconductor mesa, and a supporting base, the first end face and the second end face being arranged in a direction of a first axis, the semiconductor mesa having a first mesa portion and a second mesa portion, the supporting base mounting the semiconductor mesa; and
a first electrode disposed on the semiconductor mesa,
the first mesa portion extending from the first end face,
the first mesa portion and the second mesa portion being disposed between the first end face and the second end face,
the second mesa portion having an end,
the semiconductor mesa having a first mesa width at a boundary between the first mesa portion and the second mesa portion,
the second mesa portion having a second mesa width at the end of the second mesa portion,
the second mesa width being smaller than the first mesa width,
the second mesa portion having a width varying from the first mesa width in a direction from the boundary to the second end face,
the semiconductor mesa including a conductive semiconductor region and a core layer,
the conductive semiconductor region and the core layer extending from the first end face beyond the boundary,
the second mesa portion including a high specific-resistance region, and
the high specific-resistance region having a specific resistance higher than that of the conductive semiconductor region.

2. The quantum cascade laser according to claim 1, wherein the high specific-resistance region reaches the second end face.

3. The quantum cascade laser according to claim 1, wherein the high specific-resistance region reaches a top face of the second mesa portion,

4. The quantum cascade laser according to claim 1, wherein the high specific-resistance region separates the core layer in the second mesa portion away from the second end face.

5. The quantum cascade laser according to claim 1, wherein the high specific-resistance region separates the conductive semiconductor region in the second mesa portion away from the second end face.

6. The quantum cascade laser according to claim 1, wherein the high specific-resistance region extends from a top of the second mesa portion to the supporting base.

7. The quantum cascade laser according to claim 1, wherein
the first electrode has an end away from the end of the second mesa portion, and
the high specific-resistance region is away from the second end face.

8. The quantum cascade laser according to claim 1, further comprising an insulating film,
wherein
the second mesa portion includes a top face,
the top face has a first area and a second area,
the first area and the second area are arranged in the direction of the first axis,
the first area extends from the second area to the second end face,
the high specific-resistance region extends from the second area in a direction of a second axis intersecting the first axis, and
the insulating film is disposed on the first area.

9. The quantum cascade laser according to claim 1, wherein the first electrode is away from the second end face.

10. The quantum cascade laser according to claim 1, further comprising a second electrode disposed on the supporting base, the second electrode being away from the second end face.
